(19) United States
(12) Patent Application Publication
(10) Pub. No.: US 2024/0100573 A1
(43) Pub. Date: Mar. 28, 2024

(54) SUBSTRATE PROCESSING APPARATUS AND SUBSTRATE PROCESSING METHOD

(71) Applicant: SCREEN Holdings Co., Ltd., Kyoto (JP)

(72) Inventors: Mitsutoshi SASAKI, Kyoto (JP); Takashi IZUTA, Kyoto (JP); Manabu YAMAMOTO, Kyoto (JP)

(21) Appl. No.: 18/469,260

(22) Filed: Sep. 18, 2023

(30) Foreign Application Priority Data
Sep. 22, 2022 (JP) 2022-150779
Jun. 23, 2023 (JP) 2023-103476

(51) Int. Cl. B08B 3/04

(52) U.S. Cl. CPC B08B 3/04

(57) ABSTRACT

A substrate processing apparatus includes a processing tank, a substrate holding section, a bubble supply section, and processing liquid supply sections. The substrate holding section immerses a substrate in a processing liquid stored in the processing tank. The bubble supply section supplies bubbles to the processing liquid from below the substrate. The processing tank includes a first side wall and a second side wall. The processing liquid supply sections include one or more first processing liquid supply sections and one or more second processing liquid supply sections. The one or more first processing liquid supply sections are disposed on a side of the first side wall and supply the processing liquid toward the bubbles. The one or more second processing liquid supply sections are disposed on a side of the second side wall and supply the processing liquid toward the bubbles.

### INCORPORATION BY REFERENCE

The present application claims priority under 35 U.S.C. § 119 to Japanese Patent Application No. 2022-150779, filed on Sep. 22, 2022, and Japanese Patent Application No. 2023-103476, filed on Jun. 23, 2023. The contents of these applications are incorporated herein by reference in their entirety.

### BACKGROUND ART

The present disclosure relates to a substrate processing apparatus and a substrate processing method.

A substrate processing apparatus disclosed in Patent Literature (Japanese Patent Application Laid-Open Publication No. 2022-73307) includes a substrate holding section, a processing tank, and a plurality of bubble generating tubes. The substrate holding section holds a plurality of substrates arranged in one row of the substrates in a row direction. The processing tank stores a processing liquid in which the substrates held by the substrate holding section are to be immersed. The bubble supply pipes generate bubbles in the processing liquid by supplying a gas to the processing liquid. The flow rate of the gas supplied to end bubble generating tubes of the bubble generating tubes located below the ends of the row of substrates immersed in the processing liquid is larger than the flow rate of the gas supplied to a central bubble generating tube located below the center of the row of substrates. The above configuration can almost equalize the amount of the bubbles generated from the central bubble generating tube to the amount of the bubbles generated from each end bubble generating tube, thereby inhibiting processing unevenness in each substrate.

However, only the amount of the bubbles is controlled in the substrate processing apparatus disclosed in Patent Literature. Therefore, there is a possibility of uneven distribution of the bubbles in the treatment liquid according to a processing condition. As a result, there may be a region where bubbles are short on and around the surfaces of the substrates immersed in the processing liquid.

### SUMMARY

The present disclosure has its object of providing a substrate processing apparatus and a substrate processing method that can reduce a region where bubbles are short on and around the surfaces of the substrates.

According to an aspect of the present disclosure, a substrate processing apparatus includes a processing tank, a substrate holding section, a bubble supply section, and a plurality of processing liquid supply sections. The processing tank stores a processing liquid therein. The substrate holding section holds a substrate and immerses the substrate in the processing liquid stored in the processing tank. The bubble supply section is disposed in the processing tank and supplies bubbles to the processing liquid from below the substrate. The processing liquid supply sections are disposed at the processing tank and supply the processing liquid to an interior of the processing tank. The processing tank includes a first side wall and a second side wall that face each other. The processing liquid supply sections includes one or more first processing liquid supply sections and one or more second processing liquid supply sections. The first processing liquid supply sections are disposed on a side of the first side wall and supply the processing liquid toward the bubbles. The second processing liquid supply sections are disposed on a side of the second side wall and supply the processing liquid toward the bubbles.

In one embodiment of the present disclosure, two or more processing liquid supply sections of the processing liquid supply sections each preferably belong to at least one of groups that are mutually different. Preferably, at least one processing liquid supply section of the processing liquid supply sections belongs to each of the groups. The processing liquid supply sections belonging to the respective groups preferably supply the processing liquid toward the bubbles for periods that are mutually different for each of the groups.

In one embodiment of the present disclosure, the one or more first processing liquid supply sections are preferably provided as a plurality of first liquid supply sections. The one or more second processing liquid supply sections are preferably provided as a plurality of second liquid supply sections. Preferably, the groups preferably includes a first group, a second group, and a third group. Preferably, the first group includes at least one first processing liquid supply section of the first processing liquid supply sections and does not include the second processing liquid supply sections. Preferably, the second group includes at least one second processing liquid supply section of the second processing liquid supply sections and does not include the first processing liquid supply sections. Preferably, the third group includes at least one first processing liquid supply section of the first processing liquid supply sections and at least one second processing liquid supply section of the second processing liquid supply sections.

In one embodiment of the present disclosure, the substrate processing apparatus further includes storage and a controller. Preferably, the storage that stores therein a trained model constituted through learning training data. Preferably, the controller controls the storage. Preferably, the training data includes processing amount information and processing condition information. Preferably, the processing amount information includes information indicating a processing amount of a training substrate processed with a training processing liquid. Preferably, the processing condition information includes at least: information indicating at least one training processing liquid supply section in each of training groups; and information indicating timing of when each of the training groups supplies the training processing liquid. Preferably, the controller inputs input information to the trained model to acquire output information from the trained model. Preferably, the input information includes information indicating a target value of a processing amount of the substrate to be processed with the processing liquid. Preferably, the output information includes at least: information indicating one or more processing liquid supply sections in each of the groups; and information indicating timing of when each of the groups is to supply the processing liquid. Preferably, the controller controls the processing liquid supply sections based on the output information.

In one embodiment of the present disclosure, the substrate processing apparatus further includes a processing liquid flow rate adjustment section. Preferably, the processing liquid flow rate adjustment section adjusts a supply flow rate of the processing liquid for each of the processing liquid supply sections.

In one embodiment of the present disclosure, the bubble supply section preferably includes a plurality of bubble supply pipes. Preferably, the bubble supply pipes each receive supply of a gas to supply the bubbles to the processing liquid. Preferably, the substrate processing apparatus further includes a bubble adjustment section. Preferably, the bubble adjustment section adjusts a supply flow rate of the gas for each of the bubble supply pipes.

In one embodiment of the present disclosure, the processing liquid is preferably a rinse liquid. Preferably, the substrate holding section immerses, in the rinse liquid stored in the processing tank, the substrate having been processed with a chemical liquid stored in a chemical liquid tank different from the processing tank.

In another aspect of the present disclosure, a substrate processing apparatus includes a rinse tank, a substrate holding section, a fluid supply section, and a plurality of rinse liquid supply sections. The rinse tank stores a rinse liquid therein. The substrate holding section holds a substrate having been processed with a chemical liquid stored in a chemical liquid tank different from the rinse tank and immerses the substrate in the rinse liquid stored in the rinse tank. The fluid supply section is disposed in the rinse tank and supplies a fluid to the rinse liquid from below the substrate. The rinse liquid supply sections are disposed at the rinse tank and supply the rinse liquid to an interior of the rinse tank. The rinse tank includes a first side wall and a second side wall that face each other. The processing liquid supply sections include one or more rinse liquid supply sections and one or more second rinse liquid section. The first rinse liquid supply sections are disposed on a side of the first side wall and supply the rinse liquid to the interior of the rinse tank. The second rinse liquid supply sections are disposed on a side of the second side wall and supply the rinse liquid to the interior of the rinse tank.

In another aspect of the present disclosure, a substrate processing method is implemented by a substrate processing apparatus including a processing tank and a plurality of processing liquid supply sections. The substrate processing method includes: immersing a substrate into a processing liquid stored in the processing tank; supplying bubbles to the processing liquid from below the substrate; and controlling behavior of the bubbles by supplying the processing liquid toward the bubbles from at least one processing liquid supply section of the processing liquid supply sections. The processing tank includes a first side wall and a second side wall that face each other. The processing liquid supply sections include one or more first processing liquid supply sections and one or more second processing liquid supply sections. The first processing liquid supply sections are disposed on a side of the first side wall and supply the processing liquid toward the bubbles. The second processing liquid supply sections are disposed on a side of the second side wall and supply the processing liquid toward the bubbles.

In one embodiment of the present disclosure, preferably, two or more processing liquid supply sections of the processing liquid supply sections each belong to at least one of groups that are mutually different. Preferably, at least one processing liquid supply section of the processing liquid supply sections belongs to each of the groups. In the controlling behavior of the bubbles, preferably, the processing liquid supply sections belonging to the respective groups supply the processing liquid toward the bubbles for periods that are mutually different for each of the groups.

In one embodiment of the present disclosure, the one or more first processing liquid supply sections are preferably provided as a plurality of first liquid supply sections. The one or more second processing liquid supply sections are preferably provided as a plurality of second liquid supply sections. Preferably, the groups include a first group, a second group, and a third groups. Preferably, the first group includes at least one first processing liquid supply section of the first processing liquid supply sections and does not include the second processing liquid supply sections. Preferably, the second group includes at least one second processing liquid supply section of the second processing liquid supply sections and does not include the first processing liquid supply sections. Preferably, the third group includes at least one first processing liquid supply section of the first processing liquid supply sections and at least one second processing liquid supply section of the second processing liquid supply sections.

In one embodiment of the present disclosure, preferably, the substrate processing method further includes using a trained model in a manner to input information to a trained model to acquire output information from the trained model, the trained model being constituted through learning training data. The training data preferably includes processing amount information and processing condition information. Preferably, the processing amount information includes information indicating a processing amount of a training substrate processed with a training processing liquid. Preferably, the processing condition information includes at least: information indicating at least one training processing liquid supply section in each of training groups; and information indicating timing of when each of the training groups supplies the training processing liquid. Preferably, the input information includes information indicating a target value of a processing amount of the substrate to be processed with the processing liquid. Preferably, the output information includes at least: information indicating one or more processing liquid supply sections in each of the groups; and information indicating timing of when each of the groups is to supply the processing liquid. In the controlling behavior of the bubbles, preferably, the processing liquid supply sections are controlled based on the output information.

In one embodiment of the present disclosure, preferably, a supply flow rate of the processing liquid is adjusted for each of the processing liquid supply sections in the controlling behavior of the bubbles.

In one embodiment of the present disclosure, preferably, the substrate processing apparatus further includes a plurality of bubble supply pipes that each receive supply of a gas to supply the bubbles to the processing liquid. In the supplying bubbles, preferably, a supply flow rate of the gas is adjusted for each of the bubble supply pipes.

In one embodiment of the present disclosure, the processing liquid is preferably a rinse liquid. Preferably, in the immersing, the substrate having been processed with a chemical liquid stored in a chemical liquid tank different from the processing tank is immersed in the rinse liquid stored in the processing tank.

In another aspect of the present disclosure, a substrate processing method is implemented by a substrate processing apparatus including a rinse tank and a plurality of rinse liquid supply sections. The substrate processing method includes: immersing a substrate having been processed with a chemical liquid stored in a chemical liquid tank different from the rinse tank in a rinse liquid stored in the rinse tank; supplying a fluid to the rinse liquid from below the substrate; and supplying the rinse liquid to an interior of the rinse tank from at least one of the rinse liquid supply sections. The rinse tank includes a first side wall and a second side wall that face each other. The rinse liquid supply sections include at least one first rinse liquid supply section and at least one second rinse liquid supply section. The first rinse liquid supply section is disposed on a side of the first side wall and supplies the rinse liquid to the interior of the rinse tank. The second rinse liquid supply section is disposed on a side of the second side wall and supplies the rinse liquid to the interior of the rinse tank.

### BRIEF DESCRIPTION OF THE DRAWINGS

FIG. 1 is a schematic cross-sectional view of a substrate processing apparatus according to a first embodiment of the present disclosure.

FIG. 2 is a schematic plan view of processing liquid supply sections and a bubble supply section according to the first embodiment.

FIG. 3 is a graph representation showing a relationship between etching amount and dissolved oxygen concentration of oxygen dissolved in a processing liquid in the first embodiment.

FIG. 4 is a graph representation showing a relationship between bubble supply time and the dissolved oxygen concentration in the processing liquid in the first embodiment.

FIG. 5 illustrates an example of a table that defines groups of the processing liquid supply sections in the first embodiment.

FIG. 6 indicates control sequence in control of bubble behavior through use of first to third groups of the processing liquid supply sections in the first embodiment.

FIG. 7A illustrates a map image indicating a bubble distribution as a simulation result in a comparative example. FIG. 7B illustrates a map image indicating a bubble distribution as a simulation result in an example of the present disclosure.

FIG. 8 illustrates a map image indicating a bubble distribution as a simulation result in each step in the example.

FIG. 9A is a plan view of a substrate that explains details of the simulation in the example. FIG. 9B is a side view of the substrate and a bubble supply pipe that explains details of the simulation in the example.

FIG. 10 is a flowchart depicting a substrate processing method according to the first embodiment.

FIG. 11 is a flowchart depicting a substrate processing method according to a first variation of the first embodiment.

FIG. 12 indicates a table that defines first to fifth groups of the processing liquid supply sections according to a second variation of the first embodiment.

FIG. 13 is a schematic cross-sectional view of a substrate processing apparatus according to a third variation of the first embodiment.

FIG. 14 is a block diagram of a control device according to a fourth variation of the first embodiment.

FIG. 15 is a flowchart depicting a substrate processing method according to the fourth variation.

FIG. 16 is a block diagram of a training device according to the fourth variation.

FIG. 17 is a flowchart depicting a training method according to the fourth variation.

FIG. 18 is a diagram illustrating a substrate processing method according to a first reference example.

FIG. 19 is a diagram illustrating a substrate processing method according to a second reference example.

FIG. 20 is a diagram illustrating a substrate processing method according to a fifth variation of the first embodiment.

FIG. 21 is a schematic plan view of a substrate processing apparatus according to a second embodiment of the present disclosure.

FIG. 22 is a schematic cross-sectional view of a second rinse tank in the second embodiment.

FIG. 23 is a schematic cross-sectional view of a second chemical liquid tank in the second embodiment.

FIG. 24 is a flowchart depicting a substrate processing method according to the second embodiment.

FIG. 25 is a flowchart depicting rinsing processing on substrates in the second rinse tank in the second embodiment.

FIG. 26 is a flowchart depicting rinsing processing on substrates in the second rinse tank in a variation of the second embodiment.

### DETAILED DESCRIPTION

The following describes embodiments of the present disclosure with reference to the accompanying drawings. Note that elements that are the same or equivalent are indicated by the same reference signs in the drawings and description thereof is not repeated. In order to facilitate understanding, an X axis, a Y axis, and a Z axis are indicated in drawings as appropriate. The X axis, the Y axis, and the Z axis are perpendicular to one another. The X axis and the Y axis are parallel to the horizontal direction. The Z axis is parallel to the vertical direction. Note that the term “in plan view” means viewing an object from vertically above.

### First Embodiment

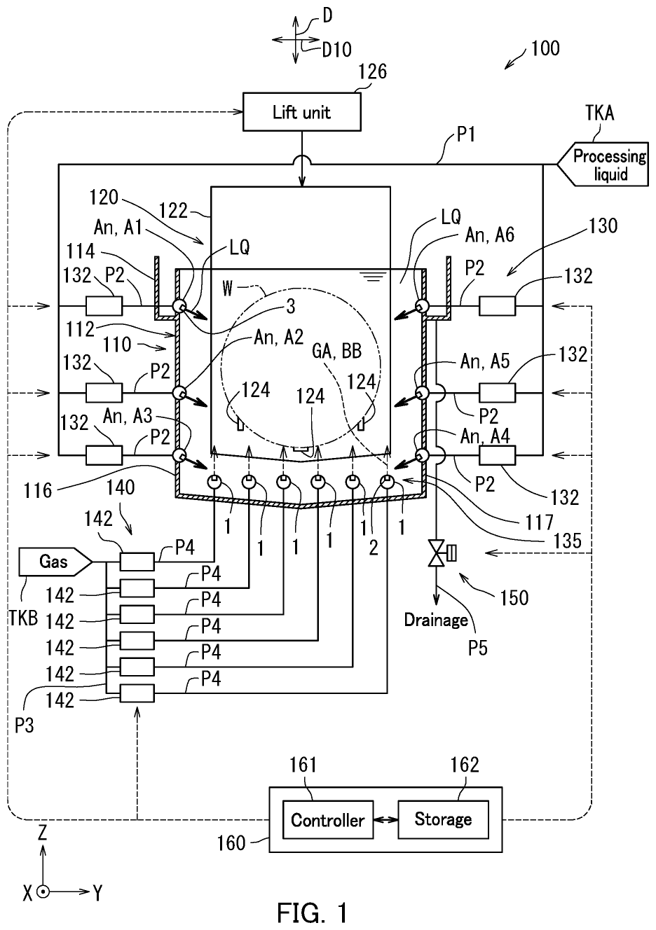

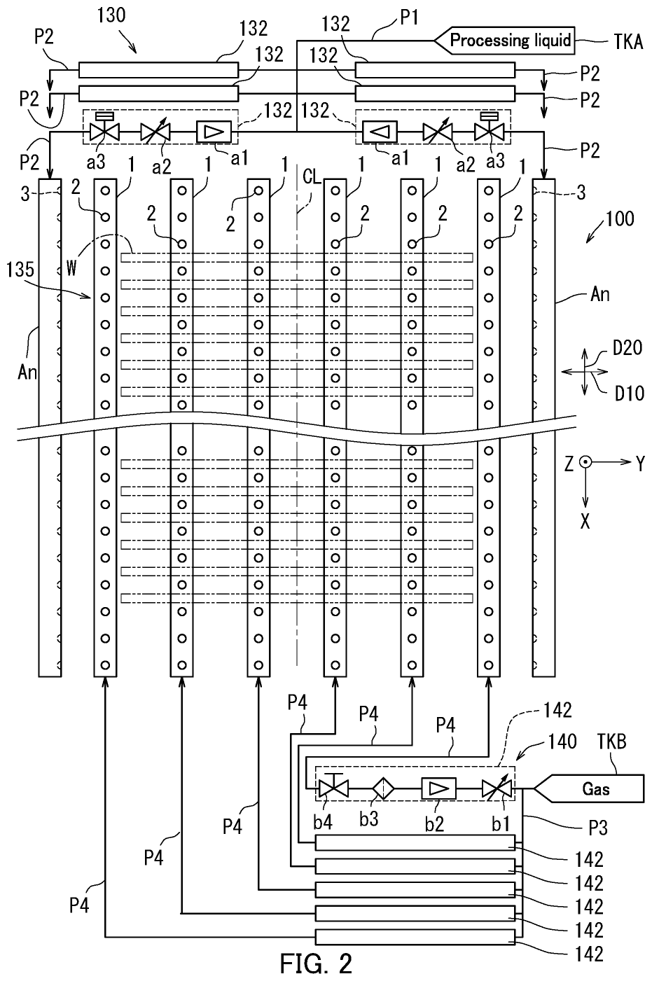

With reference to FIGS. 1 to 10, a substrate processing apparatus 100 according to a first embodiment of the present disclosure is described. With reference first to FIGS. 1 and 2, the substrate processing apparatus 100 is described. FIG. 1 is a schematic cross-sectional view of the substrate processing apparatus 100. The substrate processing apparatus 100 illustrated in FIG. 1 is of batch type and processes a plurality of substrates W in a batch with a processing liquid LQ. Specifically, the substrate processing apparatus 100 processes a plurality of substrates W constituting a lot in a batch. The lot includes 25 substrates or 50 substrates, for example. Note that the substrate processing apparatus 100 is also capable of processing a single substrate W.

The substrates W are semiconductor wafers in the first embodiment. The substrates W may be substrates for liquid crystal display device use, substrates for plasma display use, substrates for field emission display (FED) use, substrates for optical disc use, substrates for magnetic disc use, substrates for magneto-optical disc use, substrates for photomask use, ceramic substrates, and substrates for solar cell use. In the first embodiment, the surfaces of the substrates W refer to main surfaces of the substrate W.

The substrate processing apparatus 100 includes a processing tank 110, a substrate holding section 120, a plurality of processing liquid supply sections An, a processing liquid flow rate adjustment section 130, a bubble supply section 135, a bubble adjustment section 140, and a drainage section 150. Note that “n” for An represents an integer of at least 1. The substrate processing apparatus 100 further includes a common pipe P1, a plurality of supply pipes P2, a common pipe P3, a plurality of supply pipes P4, and a drainage pipe P5.

The processing tank 110 stores the processing liquid LQ therein. In the processing tank 110, the substrates W are immersed in the processing liquid LQ for processing the substrates W.

The processing liquid LQ is a chemical liquid or cleaning liquid (rinse liquid). The chemical liquid is an etching solution, for example. Examples of the chemical liquid includes dilute hydrofluoric acid (DHF), hydrofluoric acid (HF), hydrofluoric nitric acid (mixed liquid of hydrofluoric acid and nitric acid (HNO₃)), buffered hydrofluoric acid (BHF), ammonium fluoride, HFEG (mixed liquid of hydrofluoric acid and ethylene glycol), phosphoric acid (H₃PO₄), sulfuric acid, acetic acid, nitric acid, hydrochloric acid, ammonia water, hydrogen peroxide water, organic acids (e.g., citric acid and oxalic acid), organic alkalis (e.g., tetramethylammonium hydroxide (TMAH)), sulfuric acid/hydrogen peroxide mixture (SPM), ammonia hydrogen peroxide mixture (SC1), hydrochloric acid/hydrogen peroxide mixture (SC2), isopropyl alcohol (IPA), a surfactant, a corrosion inhibitor, and a hydrophobizing agent.

Examples of the cleaning liquid (rinse liquid) include deionized water, carbonated water, electrolytic ionized water, hydrogen water, ozone water, and a hydrochloric acid water with dilute concentration (e.g., about 10 ppm to 100 ppm). The cleaning liquid (rinse liquid) is a liquid used for washing out any of the chemical liquid, by-products of processing with the chemical liquid, and foreign matter from the substrate W. Cleaning treatment (rinse treatment) is a treatment for washing out any of the chemical liquid, by-products of processing with the chemical liquid, and foreign matter from the substrate W.

The processing tank 110 has a double tank structure including an inner tank 112 and an outer tank 114. The inner tank 112 and the outer tank 114 each have an upper opening open upward. The inner tank 112 stores the processing liquid LQ therein and is configured to accommodate a plurality of substrates W. The outer tank 114 is disposed around the outer surface of the upper opening of the inner tank 112. The upper edge of the outer tank 114 is higher in level than the upper edge of the inner tank 112. A portion of the processing liquid LQ that has overflown from the upper edge of the inner tank 112 is collected in the outer tank 114.

The processing tank 110 includes a first side wall 116 and a second side wall 117 that face each other in a first direction D10. Specifically, the inner tank 112 includes the first side wall 116 and the second side wall 117. The first direction D10 is substantially parallel to the horizontal direction and the surfaces of the substrates W. The first side wall 116 and the second side wall 117 extend in a vertical direction D.

The substrate holding section 120 holds a plurality of substrates W. The substrate holding section 120 is also capable of holding a single substrate W. The substrate holding section 120 immerses the substrates W aligned at intervals in the processing liquid LQ stored in the processing tank 110.

Specifically, the substrate holding section 120 moves up and down in the vertical direction D while holding the substrates W. As a result of the substrate holding section 120 moving down, the substrates W held by the substrate holding section 120 are immersed in the processing liquid LQ stored in the inner tank 112.

The substrate holding section 120 includes a main plate 122 and holding bars 124. The main plate 122 is a plate extending in the vertical direction D (Z direction). The holding bars 124 extend in the horizontal direction (Y direction) from one of the main surfaces of the main plate 122. The substrates W aligned at the intervals are held in an upright posture (vertical posture) with the lower edges of the substrates W in contact with the holding bars 124.

The substrate holding section 120 may further include a lift unit 126. The lift unit 126 brings the main plate 122 up and down between a processing position and a retraction position. Here, the processing position is a position where the substrates W held by the substrate holding section 120 are located within the inner tank 112 and the retraction position is a position where the substrates W held by the substrate holding section 120 are located above the inner tank 112. In the above configuration, as a result of the lift unit 126 moving the main plate 122 to the processing position, the substrates W held by the holding bars 124 are immersed in the processing liquid LQ. As a result, the substrates W are processed.

The processing liquid supply sections An are disposed at the processing tank 110. The processing liquid supply sections An supply the processing liquid LQ to the processing tank 110. For example, the processing liquid supply sections An supply the processing liquid LQ to the processing tank 110 in a state in which the processing liquid LQ is stored in the processing tank 110.

FIG. 2 is a schematic plan view of the processing liquid supply sections An and the bubble supply section 135. As illustrated in FIG. 2, the processing liquid supply sections An extend in a second direction D20. The second direction D20 is substantially parallel to the horizontal direction and substantially perpendicular to the surfaces of the substrates W. The first direction D10, the second direction D20, and the vertical direction D are substantially perpendicular to one another. The processing liquid supply sections An are processing liquid supply pipes, for example. Examples of the material of the processing liquid supply pipes include quartz and polyvinyl chloride (PVC).

As illustrated in FIGS. 1 and 2, the processing liquid supply sections An each are configured with a plurality of processing liquid holes 3. The processing liquid LQ is supplied from the processing liquid holes 3 of each of the processing liquid supply sections An. The processing liquid holes 3 are formed at intervals in the second direction D20. In the example illustrated in FIG. 1, the processing liquid holes 3 are directed diagonally downward.

Referring again to FIG. 1, the processing liquid supply sections An include at least one first processing liquid supply section An disposed on the side of the first side wall 116 and at least one second processing liquid supply section An disposed on the side of the second side wall 117.

In the example illustrated in FIG. 1, the processing liquid supply sections An include a plurality of first processing liquid supply sections A1 to A3 disposed on the side of the first side wall 116 and a plurality of second processing liquid supply sections A4 to A6 disposed on the side of the second side wall 117.

Specifically, the three first processing liquid supply sections A1 to A3 are disposed at the first side wall 116. The first processing liquid supply sections A1 to A3 are aligned at intervals in the vertical direction D at the first side wall 116. The first processing liquid supply section A1 is disposed uppermost. The first processing liquid supply section A3 is disposed lowermost. The first processing liquid supply section A2 is disposed in the middle. That is, the first processing liquid supply section A2 is disposed between the first processing liquid supply section A1 and the first processing liquid supply section A3 in the vertical direction D.

The three second processing liquid supply sections A4 to A6 are disposed at the second side wall 117. The second processing liquid supply sections A4 to A6 are aligned at intervals in the vertical direction D at the second side wall 117. The second processing liquid supply section A6 is disposed uppermost. The second processing liquid supply section A4 is disposed lowermost. The second processing liquid supply section A5 is disposed in the middle. That is, the second processing liquid supply section A5 is disposed between the second processing liquid supply section A6 and the second processing liquid supply section A4 in the vertical direction D.

The processing liquid flow rate adjustment section 130 adjusts, for each of the processing liquid supply sections An, the flow rate of the processing liquid LQ supplied to the processing liquid supply sections An. In other words, the processing liquid flow rate adjustment section 130 adjusts, for each of the processing liquid supply sections An, the flow rate of the processing liquid LQ supplied to the processing tank 110 by the processing liquid supply sections An.

Adjustment of the flow rate of the processing liquid LQ includes keeping the flow rate of the processing liquid LQ constant, increasing the flow rate of the processing liquid LQ, decreasing the flow rate of the processing liquid LQ, and setting the flow rate of the processing liquid LQ to zero. In the first embodiment, the processing liquid flow rate adjustment section 130 switches for each of the processing liquid supply sections An between supply and supply stop of the processing liquid LQ to the processing liquid supply section An. In other words, the processing liquid flow rate adjustment section 130 switches for each of the processing liquid supply sections An between supply and supply stop of the processing liquid LQ to the processing tank 110 from the processing liquid supply section An.

Specifically, the processing liquid flow rate adjustment section 130 includes a plurality of processing liquid flow rate adjustment mechanisms 132 for the respective processing liquid supply sections An. The supply pipes P2 are provided for the respective processing liquid supply sections An. One end of each of the supply pipes P4 is connected to a corresponding one of the processing liquid supply sections An. The other end of each of the supply pipes P2 is connected to the common pipe P1. The common pipe P1 is connected to a processing liquid supply source TKA.

The processing liquid flow rate adjustment mechanisms 132 are disposed in the respective supply pipes P2. The processing liquid flow rate adjustment mechanisms 132 each supply the processing liquid LQ supplied from the processing liquid supply source TKA and the common pipe P1 to a corresponding one of the processing liquid supply sections An through a corresponding one of the supply pipes P2. The processing liquid flow rate adjustment mechanisms 132 each adjust the flow rate of the processing liquid LQ to be supplied to a corresponding one of the processing liquid supply sections An. In other words, the processing liquid flow rate adjustment mechanisms 132 each adjust the flow rate of the processing liquid LQ to be supplied to the processing tank 110 by a corresponding one of the processing liquid supply sections An. In the first embodiment, the processing liquid flow rate adjustment mechanisms 132 each switch between supply and supply stop of the processing liquid LQ to a corresponding one of the processing liquid supply sections An. In other words, the processing liquid flow rate adjustment mechanisms 132 switch between supply and supply stop of the processing liquid LQ to the processing tank 110 from a corresponding one of the processing liquid supply sections An.

Specifically, as illustrated in FIG. 2, the processing liquid flow rate adjustment mechanisms 132 each include a flowmeter a1, an adjustment valve a2, and a valve a3. The flowmeter a1, the adjustment valve a2, and the valve a3 are disposed in the corresponding supply pipe P2 in the stated order from upstream to downstream of the supply pipe P2.

The flowmeter a1 measures the flow rate of the processing liquid LQ flowing in the supply pipe P2. The adjustment valve a2 adjusts the opening of the supply pipe P2 to adjust the flow rate of the processing liquid LQ flowing in the supply pipe P2, thereby adjusting the flow rate of the processing liquid LQ to be supplied to the corresponding processing liquid supply section An. Also, the adjustment valve b2 adjusts the flow rate of the processing liquid LQ based on the measurement result from the flowmeter a1. Note that a mass flow controller may be provided in place of the flowmeter a1 and the adjustment valve a2. The valve b3 opens and closes the supply pipe P2. That is, the valve a3 switches between supply and supply stop of the processing liquid LQ to the processing liquid supply section An from the supply pipe P2. Note that the processing liquid flow rate adjustment mechanisms 132 may each include a filter for removing foreign matter in the processing liquid LQ.

Referring back to FIG. 1, the drainage section 150 discharges processing liquid LQ collected in the outer tank 114 through the drainage pipe P5. Specifically, the drainage pipe P5 is connected to the outer tank 114. The drainage section 150 is disposed in the drainage pipe P5. The drainage section 150 includes a valve, for example, and opens and closes the flow channel of the drainage pipe P5.

The bubble supply section 135 is disposed in the interior of the processing tank 110. The bubble supply section 135 supplies a gas GA supplied from the bubble adjustment section 140 to the processing liquid LQ in the processing tank 110. Specifically, the bubble supply section 135 supplies bubbles BB of the gas GA to the processing liquid LQ in the processing tank 110. The gas GA is an inert gas, for example. Examples of the inert gas include nitrogen and argon.

The bubble supply section 135 includes at least one bubble supply pipe 1. In the first disclosure, the bubble supply section 135 includes a plurality of bubble supply pipes 1. In the example illustrated in FIG. 1, the bubble supply section 135 includes six bubble supply pipes 1. Furthermore, the number of the bubble supply pipes 1 is also not limited particularly. The bubble supply pipes 1 are bubbler tubes, for example.

Examples of the material of the bubble supply pipes 1 include quartz and synthetic resin. Examples of the synthetic resin in this case include polyether ether ketone (PEEK) and tetrafluoroethylene-perfluoroalkylvinylether copolymers (PFA).

As illustrated in FIGS. 1 and 2, each of the bubble supply pipes 1 is configured with a plurality of bubble holes 2. In the example illustrated in FIG. 1, the bubble holes 2 are directed upward in the vertical direction D. The bubble supply pipes 1 eject from the bubble holes 2 the gas GA supplied from the bubble adjustment section 140 to supply the bubbles BB to the processing liquid LQ. That is, the bubble supply pipes 1 receive supply of the gas GA and supply the bubbles BB to the processing liquid LQ.

The bubble supply pipes 1 are arranged substantially in parallel to each other at intervals in plan view. In the example illustrated in FIG. 2, the bubble supply pipes 1 are arranged symmetrically with respect to a virtual center line CL. The virtual center line CL passes through the center of each of the substrates W and extends in the second direction D20.

Specifically, the bubble supply pipes 1 are arranged substantially in parallel with each other at intervals in the first direction D10 in the processing tank 110. The bubble supply pipes 1 extend in the second direction D20. In each of the bubble supply pipes 1, the bubble holes 2 are disposed on a substantially straight line at intervals in the second direction D20. In each of the bubble supply pipes 1, each of the bubble holes 2 is provided in an upper part of the surface of the bubble supply pipe 1.

In detail, each of the bubble supply pipes 1 supplies the bubbles BB from each of the bubble holes 2 to the processing liquid LQ from below the substrates W in a state in which the substrates W are immersed in the processing liquid LQ. In the above configuration, the concentration of oxygen dissolved in the processing liquid LQ can be reduced compared with a case in which the bubbles BB are not supplied. As a result, the substrates W immersed in the processing liquid LQ can be effectively processed with the processing liquid LQ. This is described later in detail. Supply of the bubbles BB can achieve effective replacement of the processing liquid LQ in contact with the surfaces of the substrates W by fresh processing liquid LQ.

The bubble adjustment section 140 adjusts the amount of the bubbles BB to be supplied to the processing liquid LQ by adjusting, for each of the bubble supply pipes 1, the flow rate of the gas GA to be supplied to the bubble supply pipe 1. Adjustment of the flow rate of the gas GA includes keeping the flow rate of the gas GA constant, increasing the flow rate of the gas GA, decreasing the flow rate of the gas GA, and setting the flow rate of the gas GA to zero. In the first disclosure, the bubble adjustment section 140 switches, for each of the bubble supply pipes 1, between supply and supply stop of the gas GA to the bubble supply pipe 1. In other words, the bubble adjustment section 140 switches, for each of the bubble supply pipes 1, between supply and supply stop of the bubbles BB to the processing liquid LQ in the processing tank 110 from the bubble supply pipe 1.

Specifically, the bubble adjustment section 140 includes a plurality of bubble adjustment mechanisms 142 for the respective bubble supply pipes 1. The supply pipes P4 are provided for the respective bubble adjustment mechanisms 142. One end of each of the supply pipes P4 is connected to a corresponding one of the bubble supply pipes 1. The other end of each of the supply pipes P4 is connected to the common pipe P3. The common pipe P3 is connected to a gas supply source TKB.

The bubble adjustment mechanisms 142 are disposed in the respective supply pipes P4. The bubble adjustment mechanisms 142 each supply the gas GA supplied from the gas supply source TKB and the common pipe P3 to a corresponding one of the bubble supply pipes 1 through a corresponding one of the supply pipes P4. The bubble adjustment mechanisms 142 each adjust the flow rate of the gas GA to be supplied to a corresponding one of the bubble supply pipes 1. As a result, the amount of the bubbles BB to be supplied to the processing liquid LQ is adjusted for each of the bubble supply pipes 1. In the first embodiment, the bubble adjustment mechanisms 142 each switch between supply and supply stop of the gas GA to a corresponding one of the bubble supply pipes 1. In other words, the bubble adjustment mechanisms 142 each switch between supply and supply stop of the gas GA to the processing liquid LQ in the processing tank 110 from a corresponding one of the bubble supply pipes 1 in the first embodiment.

Specifically, as illustrated in FIG. 2, each of the bubble adjustment mechanisms 142 includes an adjustment valve b1, a flowmeter b2, a filter b3, and a valve b4. The adjustment valve b1, the flowmeter b2, the filter b3, and the valve b4 are disposed in each of the supply pipes P4 in the stated order from upstream to downstream of the supply pipe P4.

The adjustment valve b1 adjusts the opening of a corresponding supply pipe P4 to adjust the flow rate of the gas GA flowing in the supply pipe P4, thereby adjusting the flow rate of the gas GA to be supplied to a corresponding bubble supply pipe 1. The flowmeter b2 measures the flow rate of the gas GA flowing in the supply pipe P4. The adjustment valve b1 adjusts the flow rate of the gas GA based on the measurement result from the flowmeter b2. Note that a mass flow controller may be provided in place of the adjustment valve b1 and the flowmeter b2, for example.

The filter b3 removes foreign matter from the gas GA flowing in the supply pipe P4. The valve b4 opens and closes the supply pipe P4. That is, the valve b4 switches between supply and supply stop of the gas GA to the bubble supply pipe 1 from the supply pipe P4.

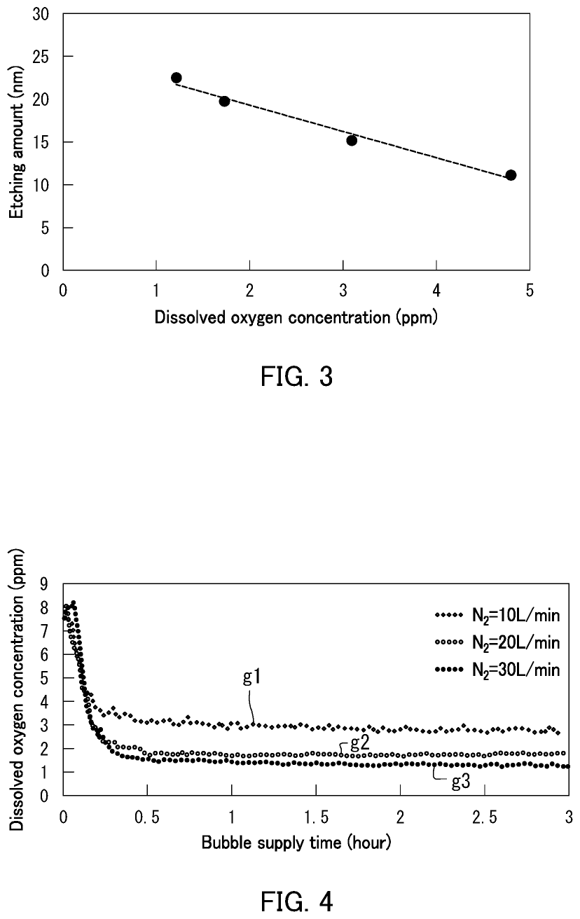

With reference to FIG. 3, the relationship between dissolved oxygen concentration and etching amount is described next. FIG. 3 is a graph representation showing the relationship between etching amount and dissolved oxygen concentration of oxygen dissolved in the processing liquid LQ. The horizontal axis indicates the dissolved oxygen concentration (ppm) in the processing liquid LQ and the vertical axis indicates the etching amount of a substrate W.

FIG. 3 shows an example in a case in which TMAH is used as the processing liquid LQ. The concentration of the TMAH was 0.31%. The gas GA was nitrogen. Accordingly, the bubbles BB were bubbles of nitrogen. A polysilicon film (polysilicon layer) has been formed on the substrate W. FIG. 3 shows the etching amount of the polysilicon film when the substrate W is immersed in the TMAH. The etching amount is a value obtained by subtracting the thickness of the polysilicon film after immersion in the TMAH from the thickness of the polysilicon film before the immersion therein. The etching amount may be also referred to below as “etching amount of the substrate W”. In present specification, “after immersion of the substrate W” means “after processing is completed as a result of immersion of the substrate W and the substrate W is pulled out of the processing liquid LQ”.

As shown in FIG. 3, the etching amount (processing amount) of the substrate W increases as the dissolved oxygen concentration is decreased. The etching amount (processing amount) was substantially in direct proportion to the dissolved oxygen concentration. The proportional constant was “negative”.

With reference to FIG. 4, the relationship between the dissolved oxygen concentration and supply time of the bubbles BB is described next. FIG. 4 is a graph representation showing the relationship between the supply time of the bubbles BB and the dissolved oxygen concentration in the processing liquid LQ. The horizontal axis indicates the supply time (hour) of the bubbles BB and the vertical axis indicates the dissolved oxygen concentration (ppm) in the processing liquid LQ.

FIG. 4 shows an example in a case in which TMAH was used as the processing liquid LQ. The concentration of the TMAH was 0.31%. The gas GA for generating the bubbles BB was nitrogen. Accordingly, the bubbles BB were bubbles of nitrogen. Plots g1 indicate the dissolved oxygen concentration when the flow rate of the gas GA was 10 L/min. Plots g2 indicate the dissolved oxygen concentration when the flow rate of the gas GA was 20 L/min. Plots g3 indicate the dissolved oxygen concentration when the flow rate of the gas GA was 30 L/min. The flow rate of the gas GA in this case means a flow rate of the gas GA supplied to one bubble supply pipe 1.

As can be understood from the plots g1 to g3, the dissolved oxygen concentration in the processing liquid LQ became substantially constant after about one hour. Furthermore, in a state in which the dissolved oxygen concentration was substantially constant, the dissolved oxygen concentration in the processing liquid LQ decreased as the flow rate of the gas GA was increased. In other words, in a state in which the dissolved oxygen concentration was substantially constant, the dissolved oxygen concentration in the processing liquid LQ decreased as the amount of the bubbles BB supplied to the processing liquid LQ was increased. This is because the higher the flow rate of the gas GA is, the larger the amount of the bubbles BB supplied to the processing liquid LQ is.

The following was inferred from the plots g1 to g3. That is, it was inferred that when there is a distribution of the bubbles BB in the processing liquid LQ in the processing tank 110, the dissolved oxygen concentration is lower in an area with a larger amount of the bubbles BB in the processing liquid LQ and is higher in an area with a smaller amount of the bubbles BB in the processing liquid LQ. The discloser of the present application has confirmed by experiment that the above inference is correct.

As described so far with reference to FIGS. 3 and 4, the dissolved oxygen concentration in the processing liquid LQ decreases as the amount of the bubbles BB supplied to the processing liquid LQ is increased. As such, the etching amount (processing amount) of the substrate W increased as the dissolved oxygen concentration in the processing liquid LQ was decreased.

That is, the larger the amount of the bubbles BB supplied to the processing liquid LQ is, the larger the etching amount (processing amount) of the substrate W is. In other words, the higher the flow rate of the gas GA for generating the bubbles BB was, the larger the etching amount (processing amount) of the substrate W was. By contrast, the smaller the amount of the bubbles BB supplied to the processing liquid LQ was, the smaller the etching amount (processing amount) of the substrate W was. In other words, the lower the flow rate of the gas GA for generating the bubbles BB was, the smaller the etching amount (processing amount) of the substrate W was.

Furthermore, it was inferred from the graph representations of FIGS. 3 and 4 that when there is a distribution of the bubbles BB in the processing liquid LQ in the processing tank 110, the etching amount (processing amount) of the substrate W is larger in an area with a larger amount of the bubbles BB in the processing liquid LQ and is smaller in an area with a smaller amount of the bubbles BB in the processing liquid LQ. Likewise, it was inferred that when there is a distribution of the bubbles BB in the processing liquid LQ in the processing tank 110, the etch rate (processing amount) of the substrate W is higher in an area with a larger amount of the bubbles BB in the processing liquid LQ and is lower in an area with a smaller amount of the bubbles BB in the processing liquid LQ. The discloser of the present application has confirmed by experiment that the above inference is correct.

Referring back to FIG. 1, the control device 160 controls each element of the substrate processing apparatus 100. For example, the control device 160 controls the substrate holding section 120, the processing liquid flow rate adjustment section 130, the bubble adjustment section 140, and the drainage section 150.

The control device 160 includes a controller 161 and storage 162. The controller 161 includes a processor such as a central processing unit (CPU) or a graphics processing unit (GPU). The storage 162 includes a storage device and stores data and computer programs therein. The processor of the controller 161 executes the computer programs stored in the storage device of the storage 162 to control each element of the substrate processing apparatus 100. For example, the storage 162 includes a main storage device such as semiconductor memory and an auxiliary storage device such as semiconductor memory or a hard disk drive. The storage 162 may include a removable medium such as an optical disc. The storage 162 may be a non-transitory computer-readable storage medium, for example. The control device 160 may include an input device and a display device.

Continuing to refer to FIG. 1, the details of the processing liquid supply sections An are described. Of the first processing liquid supply sections A1 to A3, at least one first processing liquid supply section An supplies the processing liquid LQ toward the bubbles BB in the rise. Of the second processing liquid supply sections A4 to A6, at least one second processing liquid supply section An supplies the processing liquid LQ toward the bubbles BB in the rise. Accordingly, according to the first embodiment, the controller 161 individually controls supply and supply stop of the processing liquid LQ from the first processing liquid supply section An and supply and supply stop of the processing liquid LQ from the second processing liquid supply section An through the processing liquid flow rate adjustment section 130 to achieve control of the behavior of the many bubbles BB rising in the processing liquid LQ. As a result, areas with an insufficient amount of the bubbles BB can be reduced on and around the surfaces of the substrates W. Thus, the dissolved oxygen concentration in the processing liquid LQ can be reduced over the entirety of each of the surfaces of the substrates W, thereby reducing unevenness in processing with the processing liquid LQ in the in-plane of each substrate W.

Specifically, at least one of the first processing liquid supply sections An ejects the processing liquid LQ in a direction intersecting the vertical direction D from the side of the first side wall 116 to generate a flow of the processing liquid LQ toward the bubbles BB in the rise. As a result, the behavior of the bubbles BB can be controlled. In the example illustrated in FIG. 1, the first processing liquid supply sections An eject the processing liquid LQ diagonally downward from the side of the first side wall 116. At least one of the second processing liquid supply sections An also ejects the processing liquid LQ in a direction intersecting the vertical direction D from the side of the second side wall 117 to generate a flow of the processing liquid LQ toward the bubbles BB in the rise. As a result, the behavior of the bubbles BB can be controlled. In the example illustrated in FIG. 1, the second processing liquid supply sections An eject the processing liquid LQ diagonally downward from the side of the second side wall 117.

Continuing to refer to FIG. 1, groups each constituted by one or more processing liquid supply sections An are described. Of the processing liquid supply sections An, two or more processing liquid supply sections An each belong to at least one group of mutually different groups. The groups are control units of the processing liquid supply sections An. In the above configuration, the controller 161 controls the processing liquid supply sections An on a group-by-group basis through the processing liquid flow rate adjustment section 130.

One processing liquid supply section An may belong to one group and one processing liquid supply section An may belong to a plurality of groups. To each of the groups, at least one processing liquid supply section An belongs. In the above configuration, one processing liquid supply section An may belong to one group and a plurality of processing liquid supply sections An may belong to one group. Furthermore, some of the processing liquid supply sections An may not belong to any of the groups. In this case, the processing liquid supply section An that does not belong to any of the groups is not used in bubble behavior control. In other words, only the processing liquid supply sections An belonging to any of the groups are used in bubble behavior control.

While sequentially switching each group, the controller 161 causes the processing liquid supply section(s) An in the corresponding group to supply the processing liquid LQ toward the bubbles BB in the processing liquid LQ in the processing tank 110 through the processing liquid flow rate adjustment section 130.

Each processing liquid supply section An belonging to any of the groups supplies the processing liquid LQ toward the bubbles BB during a corresponding one of periods that are mutually different for each of the groups. In the above configuration, the flow of the processing liquid LQ in the processing tank 110 differs from group to group in the first embodiment. Therefore, the different flows can act on many the bubbles BB in the rise in the processing liquid LQ for the different periods. As a result, areas with an insufficient amount of the bubbles BB can be further effectively reduced on and around the surfaces of the substrates W. Thus, the dissolved oxygen concentration in the processing liquid LQ can be effectively reduced over the entirety of each of the surfaces of the substrates W, thereby reducing unevenness in processing with the processing liquid LQ in the in-plane of each substrate W. In the present specification, the “periods that are mutually different for each of the groups” refer to periods that are mutually different from each other on the time axis, for example. That is, the “periods that are mutually different for each of the groups” in the present specification refer to time ranges mutually different for each other on the time axis, for example.

In the following, the groups include a first group G1, a second group G2, and a third group G3 in the first embodiment as one example.

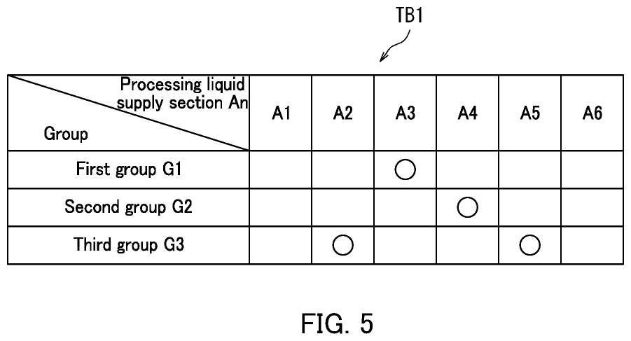

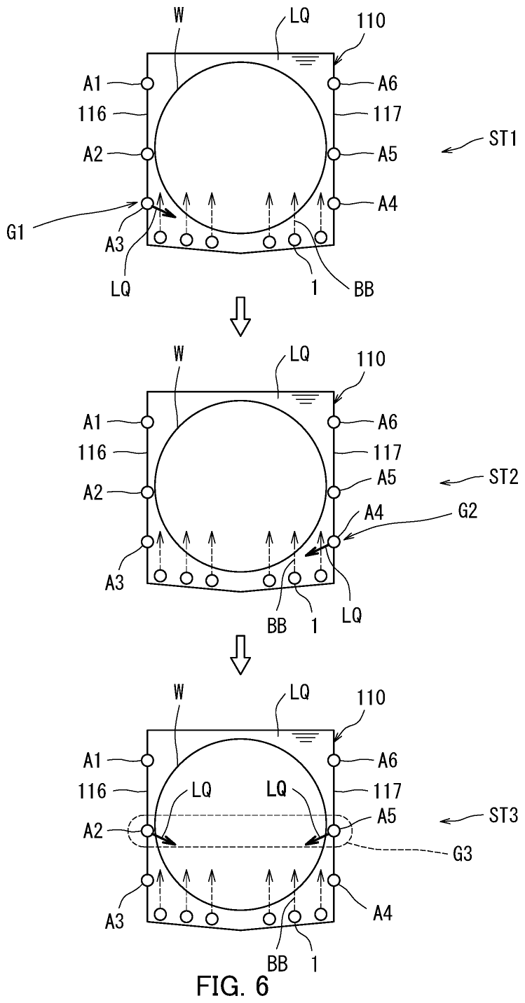

Behavior control of the bubbles BB by the processing liquid supply sections An in each of the first group G1 to the third group G3 is described next with reference to FIGS. 5 and 6.

FIG. 5 indicates a table TB1 that defines the first group G1 to the third group G3 of the processing liquid supply sections An. As indicated in the table TB1 in FIG. 5, the first group G1, the second group G2, and the third group G3 are set for the substrate processing apparatus 100.

The first group G1 includes at least one first processing liquid supply section A3 of the first processing liquid supply sections A1 to A3 illustrated in FIG. 1 and does not include the second processing liquid supply sections A4 to A6. That is, the first group G1 includes only the first processing liquid supply section A3.

The second group G2 includes at least one second processing liquid supply section A4 of the second processing liquid supply sections A4 to A6 and does not include the first processing liquid supply sections A1 to A3. That is, the second group G2 includes only the second processing liquid supply section A4.

The third group G3 includes at least one first processing liquid supply section A2 of the first processing liquid supply sections A1 to A3 and at least one second processing liquid supply section A5 of the second processing liquid supply sections A4 to A6. The third group G3 includes the first processing liquid supply section A2 and the second processing liquid supply section A5.

FIG. 6 illustrates control sequence in behavior control of the bubbles BB using the first group G1 to the third group G3 of the processing liquid supply sections An.

First in Step ST1, the first processing liquid supply section A3 belonging to the first group G1 supplies the processing liquid LQ toward the bubbles BB in a first predetermined period T1 as illustrated in FIG. 6.

Next in Step ST2, the second processing liquid supply section A4 belonging to the second group G2 supplies the processing liquid LQ toward the bubbles BB in a second predetermined period T2 after elapse of the first predetermined period T1.

Next in Step ST3, the first processing liquid supply section A2 and the second processing liquid supply section A5 each belonging to the third group G3 supply the processing liquid LQ toward the bubbles BB in a third predetermined period T3 after elapse of the second predetermined period T2.

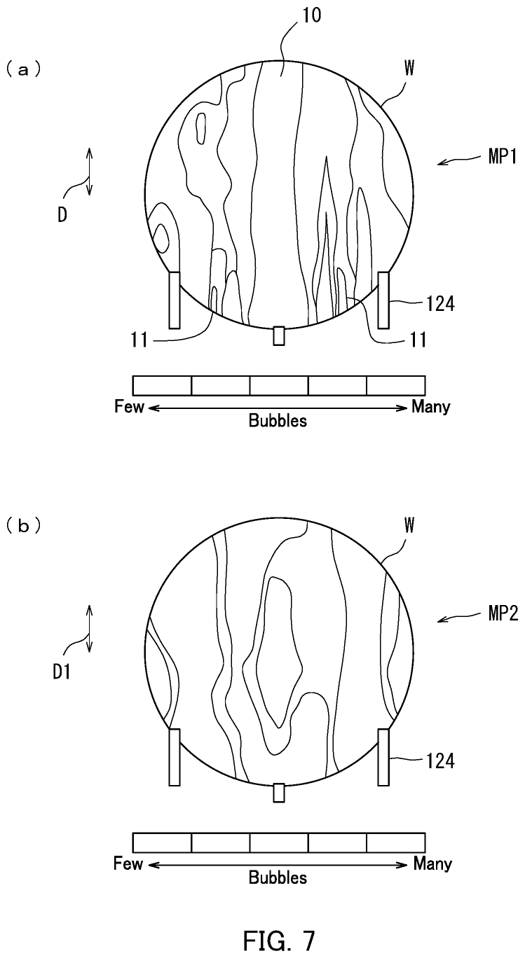

As has been described so far with reference to FIG. 6, the behavior of the bubbles BB is controlled by using the first group G1 to the third group G3 at different timings according to the first embodiment. As a result, areas with an insufficient amount of the bubbles BB can be further effectively reduced on and around the surfaces of the substrates W. The above has been proved by an example described with reference to FIGS. 7A to 9B. Note that in the first embodiment, the first predetermined period T1, the second predetermined period T2, and the third predetermined period T3 are consecutive periods with different timings and have the same length.

FIG. 7A illustrates a map image MP1 indicating a distribution of the bubbles BB as a simulation result according to a comparative example. FIG. 7B illustrates a map image MP2 indicating a distribution of the bubbles BB as a simulation result according to the example of the present disclosure. The map images MP1 and MP2 each indicate the amount of the bubbles BB passing upward over the surface of substrate W. The details of the above point are described later. Each of the map images MP1 and MP2 indicates that the denser the dots are, the larger the amount of the bubbles BB passing thereover is. A blank area with no dots indicates an area with the smallest amount of the bubbles BB passing thereover. Note that in reality, the amount of the bubbles BB gradually changes in each of the map images MP1 and MP2. However, the amount of the bubbles BB is shown in four levels for simplicity.

In the example illustrated in FIG. 7B, a simulation was performed assuming the use of the substrate processing apparatus 100 illustrated in FIG. 1. In the following, the simulation may be also referred to below as “bubble behavior simulation”. The simulation was performed using a simulation device (not illustrated). The simulation device is a computer including a processor and a storage device.

Furthermore, Steps ST1 to ST3 illustrated in FIG. 6 were reproduced by the simulation in the example. Simulation conditions in the example were as follows. That is, the supply amount of the processing liquid LQ from the first processing liquid supply section A3 in Step ST1 was set to 30 L/min. The supply amount of the processing liquid LQ from the second processing liquid supply section A4 in Step ST2 was set to 30 L/min. The supply amount of the processing liquid LQ from the first processing liquid supply section A2 in Step ST3 was set to 20 L/min and the supply amount of the processing liquid LQ from the second processing liquid supply section A5 in Step ST3 was set to 20 L/min. Each of Steps ST1 to ST3 was performed for 8 seconds. That is, the total time for executing Steps ST1 to ST3 was 24 seconds. Furthermore, the flow rate of the gas GA to be supplied to the bubble supply pipes 1 was set to 5 L/min per one bubble supply pipe 1. Furthermore, the diameter of the bubble holes 2 in each of the bubble supply pipes 1 was set to 0.2 mm. The number of the bubble holes 2 in each of the bubble supply pipes 1 was set to 60. The intervals of the bubble hoes 2 in each of the bubble supply pipes 1 were set to 5 mm. The diameter of the processing liquid holes 3 in each of the processing liquid supply sections An was set to 1 mm. The number of the processing liquid holes 3 in each of the processing liquid supply sections An was set to 70. The intervals of the processing liquid holes 3 in each of the processing liquid supply sections An were set to 5 mm.

By contrast, in the comparative example illustrated in FIG. 7A, a simulation was performed assuming the use of a substrate processing apparatus with a configuration of the substrate processing apparatus 100 in FIG. 1 from which the processing liquid supply sections An have been removed. Simulation conditions in the comparative example were as follows. That is, in the comparative example, upward supply of the processing liquid LQ from holes of a punch plate disposed below bubble supply pipes was reproduced. The supply flow rate of the processing liquid LQ was 20 L/min in total. The conditions for the bubble supply pipes were the same as those in the example. Furthermore, the processing time was 24 seconds.

As illustrated in FIG. 7A, the amount of passing bubbles BB is small in an area (blank area) extending in the vertical direction D in the central part of the substrate W in the comparative example. Furthermore, the amount of passing bubbles BB was also small in areas 11 (blank areas) in the lower parts of the substrate W. It was accordingly inferred that the etch rate is smaller in the areas 10 and 11 than in the other areas of the substrate W. That is, it was inferred that unevenness in processing with the processing liquid LQ will occur in the in-plane of the substrate W in the comparative example.

By contrast, no white areas were present in the map image MP2 in the example as illustrated in FIG. 7B. That is, the amount of passing bubbles BB was large over the entire surface of the substrate W in the example compared with that in the comparative example. Therefore, it was inferred that difference in etch rate among areas in the surface of the substrate W was smaller in the example than in the comparative example. That is, it was inferred that unevenness in processing with the processing liquid LQ was reduced in the in-plane of the substrate W in the example compared with the comparative example.

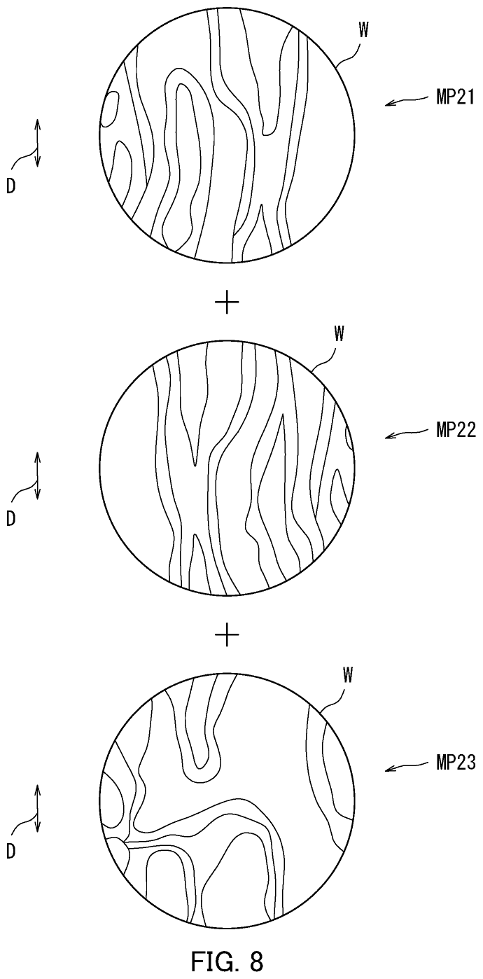

The simulation in the above example is described next in detail with reference to FIGS. 6 to 9. FIG. 8 illustrates map images MP21 to MP23 of respective distributions of the bubbles BB in Steps ST1 to ST3 (FIG. 6) as results of the simulation in the example of the present disclosure. The method for representing the amount of the bubbles BB in the map images MP21 to MP23 is the same as the method for representing the amount of the bubbles BB in the map images MP1 and MP2 in FIGS. 7A and 7B.

As illustrated in FIGS. 6 and 8, the map image MP21 indicates the amount of the bubbles BB passing upward over the surface of the substrate W in Step ST1. The map image MP22 indicates the amount of the bubbles BB passing upward over the surface of the substrate W in Step ST2. The map image MP23 indicates the amount of the bubbles BB passing upward over the surface of substrate W in Step ST3. An image in which the map image MP21, the map image MP22, and the map image MP23 are superimposed is the map image MP2 in the example illustrated in FIG. 7B.

As illustrated in FIGS. 7B and 8, as a result of generation of different distributions of the bubbles BB in Steps ST1 to ST3, areas with an insufficient amount of the bubbles BB were reduced on and around the surface of the substrate W through Steps ST1 to ST3.

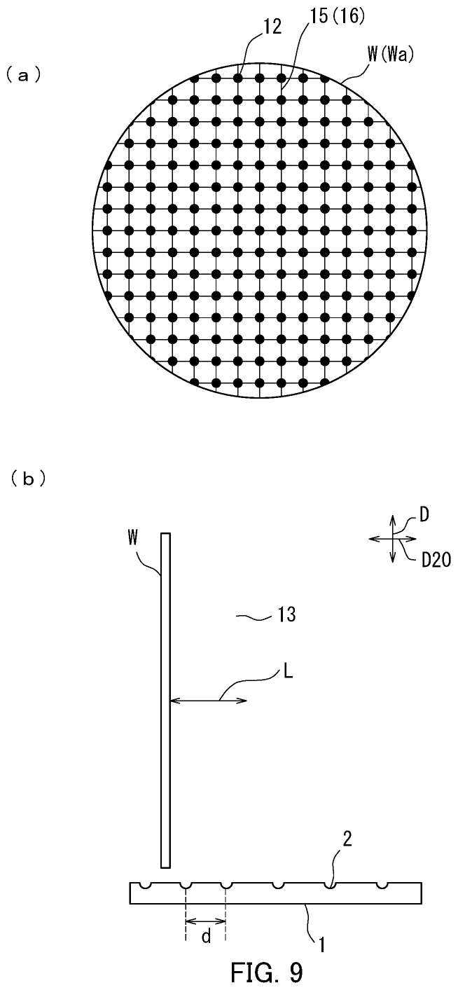

FIG. 9A is a plan view of a substrate W that explains details of the simulation in the example.

As illustrated in FIG. 9A, many monitoring points 12 for monitoring the bubbles BB were set on the surface of the substrate W in the simulation. At each of the monitoring points 12, the number of the bubbles BB passing upward over the monitoring point 12 was counted in the simulation. For example, the map image MP21 in FIG. 8 was created by plotting the accumulated values of the numbers of the bubbles BB passing over the respective monitoring points 12 during 8 seconds in Step ST1 (FIG. 6). The same applied to the map images MP22 and MP23. As such, the map image MP2 of FIG. 7B indicates the accumulated values of the numbers of the passing bubbles BB passing over the respective monitoring points 12 through Steps ST1 to ST3. Note that the accumulated values of the numbers of the bubbles BB passing over the monitoring points 12 are indicated also in the map image MP1 of the comparative example illustrated in FIG. 7A in a manner similar to that in the example.

Note that areas 15 each with four monitoring points 12 as apexes are set in the substrate W. As a result, a plurality of areas 15 are set in the substrate W. In the example illustrated in FIG. 9A, the areas 15 are square in shape.

FIG. 9B is a side view of the substrate W and a bubble supply pipe 1 that explains details of the simulation in the example. As illustrated in FIG. 9B, it is assumed in the simulation that a plurality of bubble hoes 2 are arranged at regular intervals d in the bubble supply pipe 1. Each of the intervals d was 5 mm. The number of the bubbles BB passing over an area 13 was counted at each of the monitoring points 12. The area 13 has a width L of 10 mm. That is, the number of the bubbles BB passing in a range with the width L from the surface of the substrate W was counted at each of the monitoring points 12. The same applied to the comparative example.

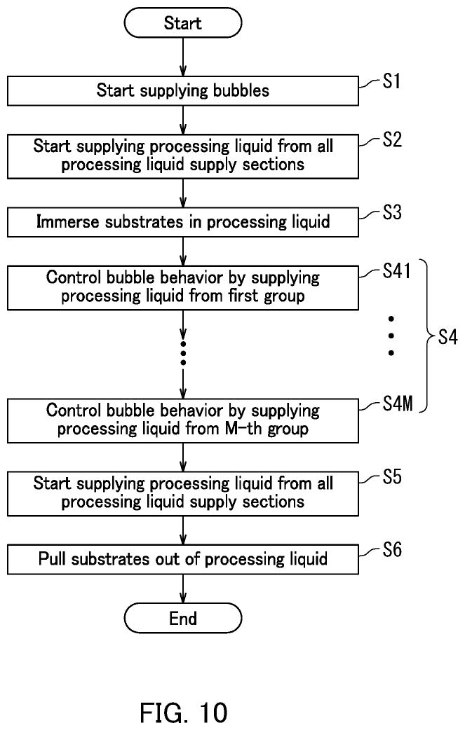

With reference to FIGS. 1 and 10, a substrate processing method according to the first embodiment is described next. The substrate processing method is implemented by the substrate processing apparatus 100. FIG. 10 is a flowchart depicting the substrate processing method according to the first embodiment. As depicted in FIG. 10, the substrate processing method includes Steps S1 to S6. Steps S1 to S6 are executed under control of the controller 161. In the description of the substrate processing method, the first group G1 to the M-th group GM are set in the substrate processing apparatus 100. “M” represents an integer of at least 2.

First in Step S1, each of the bubble supply pipes 1 of the bubble supply section 135 starts supply of the bubbles BB toward the processing liquid LQ stored in the processing tank 110 from below the substrates W as illustrated in FIGS. 1 and 10. Step S1 corresponds to an example of the “supplying bubbles” in the present disclosure.

Next in Step S2, supply of the processing liquid LQ from all of the processing liquid supply sections An toward the processing liquid LQ stored in the processing tank 110 starts.

Next in Step S3, the substrate holding section 120 immerses the substrates W in the processing liquid LQ stored in the processing tank 110. Step S3 corresponds to an example of the “immersing” in the present disclosure.

Next in Step S4, the behavior of the bubbles BB is controlled in a manner that the processing liquid LQ is supplied toward the bubbles BB from at least one processing liquid supply section An while the processing liquid supply sections An are switched. As such, the distribution of the amount of the bubbles BB on and around the surfaces of the substrates W can be prevented from being skewed according to the substrate processing method of the first embodiment. In other words, areas with an insufficient amount of the bubbles BB can be reduced in and around the surfaces of the substrates W. As a result, the dissolved oxygen concentration in the processing liquid LQ can be reduced over the entirety of each of the surfaces of the substrates W, thereby reducing unevenness in processing with the processing liquid LQ in the in-plane of each substrate W. Step S4 corresponds to an example of the “controlling behavior of the bubbles” in the present disclosure.

Specifically, Step S4 includes Steps S41, S42, S43, S44, . . . , and S4M. First in Step S41, a processing liquid supply section An belonging to the first group G1 supplies the processing liquid LQ toward the bubbles BB. Next in Step S42, a processing liquid supply section An belonging to the second group G2 supplies the processing liquid LQ toward the bubbles BB. Thereafter, Steps S43, S44, . . . , and S4M are executed in a sequential manner. In Step S4M, a processing liquid supply section An belonging to the M-th group GM supplies the processing liquid LQ toward the bubbles BB. In the manner described above, the processing liquid supply sections An belonging to the respective groups supply the processing liquid LQ toward the bubbles BB for different periods that are mutually different for each of the groups.

Next in Step S5, all of the processing liquid supply sections An start supply of the processing liquid LQ toward the processing liquid LQ stored in the processing tank 110.

Next in Step S6, the substrate holding section 120 pulls the substrates W out of the processing liquid LQ. The substrate processing method ends then.

As has been described so far with reference to FIG. 10, according to the first embodiment, the processing liquid LQ is supplied from all of the processing liquid supply sections An (Step S2) before the substrates W are immersed in the processing liquid LQ. In addition, the processing liquid LQ is supplied from all of the processing liquid supply sections An (Step S5) before the substrates W are pulled up of the processing liquid LQ. As a result, stagnation of the processing liquid LQ stored in the processing tank 110 can be inhibited. In addition, displacement of the substrates W can be inhibited. Note that for the same purpose as above, it is preferable to supply the processing liquid LQ from all of the processing liquid supply sections An even during standby.

### (First Variation)

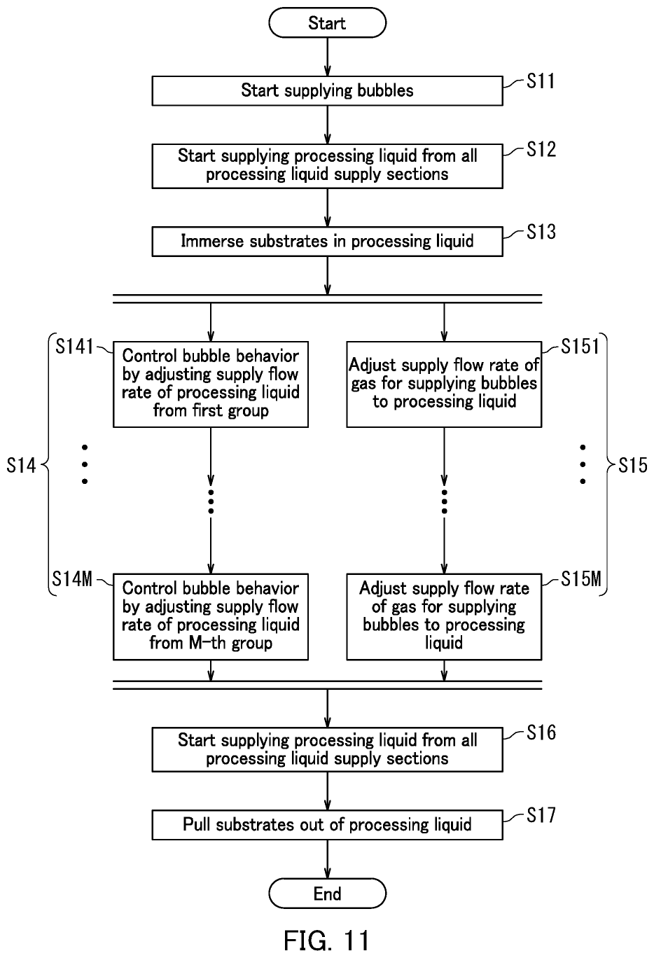

With reference to FIGS. 1 and 11, a first variation of the first embodiment is described. The first variation differs from the above embodiment in which supply start and supply stop of the processing liquid LQ and supply start and supply stop of the gas GA are executed. The main difference of the first variation from the first embodiment lies in that adjustment of the supply flow rate of the processing liquid LQ and adjustment of the supply flow rate of the gas GA for generation the bubbles BB are executed in a precise manner. The following mainly describes difference of the first variation from the first embodiment.

In the first variation, the processing liquid flow rate adjustment section 130 of the substrate processing apparatus 100 adjusts the supply flow rate of the processing liquid LQ for each of the processing liquid supply sections An. In the above configuration, the flow of the processing liquid LQ in the processing tank 110 can be further precisely controlled in the first variation. As such, behavior of many bubbles BB rising in the processing liquid LQ can be further precisely controlled. This can achieve further reduction in areas with an insufficient amount of the bubbles BB on and around the surfaces of the substrates W, thereby further reducing the dissolved oxygen concentration in the processing liquid LQ over the entirety of each of the surfaces of the substrates W. Reduction in dissolved oxygen concentration can further reduce unevenness in processing with the processing liquid LQ in the in-plane of each substrate W.

In the first variation, adjustment of the supply flow rate of the processing liquid LQ includes change of the supply flow rate of the processing liquid LQ supplied from a processing liquid supply section An in one group or change of the supply flow rate of the processing liquid LQ supplied from processing liquid supply sections An in a plurality of groups in addition to supply start and supply stop of the processing liquid LQ. Change of the supply flow rate of the processing liquid LQ includes stepwise change of the flow rate or continuous change of the flow rate.

Furthermore, the bubble adjustment section 140 adjusts the supply flow rate of the gas GA for generating the bubbles BB for each of the bubble supply pipes 1 in the first variation. In the above configuration, behavior of many bubbles BB rising in the processing liquid LQ can be further precisely controlled. As a result, the bubbles BB can be distributed over the entirety of each of the surfaces of the substrates W, thereby further reducing the dissolved oxygen concentration in the processing liquid LQ over the entirety of each of the surfaces of the substrates W. Thus, unevenness in processing with the processing liquid LQ can be further reduced in the in-plane of each substrate W.

In the first variation, adjustment of the supply flow rate of the gas GA includes change of the supply flow rate of the gas GA in addition to supply start and supply stop of the gas GA. Change of the supply flow rate of the gas GA includes stepwise change of the flow rate or continuous change of the flow rate.

With reference to FIG. 11, a substrate processing method according to the first variation is described next. The substrate processing method is implemented by the substrate processing apparatus 100. FIG. 11 is a flowchart depicting the substrate processing method according to the first variation of the first embodiment. As depicted in FIG. 11, the substrate processing method includes Steps S11 to S17. Steps S11 to S17 are executed under control of the controller 161.

Steps S11 to S13 in FIG. 11 are the same as S1 to S3 in FIG. 10, respectively.

Following Steps S13, Steps S14 and S15 are executed in parallel as illustrated in FIGS. 1 and 11.

In Step S14, the supply flow rate of the processing liquid LQ is adjusted by the processing liquid flow rate adjustment section 130 for each of the processing liquid supply sections An in the first group G1 to the M-th group GM.

Specifically, Step S14 includes Steps S141, S142, S143, S144, . . . , and S14M. First in Step S141, the processing liquid flow rate adjustment section 130 adjusts the supply flow rate of the processing liquid LQ supplied from a processing liquid supply section An belonging to the first group G1 to control behavior of the bubbles BB. Next in Step S142, the processing liquid flow rate adjustment section 130 adjusts the supply flow rate of the processing liquid LQ supplied from a processing liquid supply section An belonging to the second group G2 to control behavior of the bubbles BB. Thereafter, Steps S143, S144, . . . , and S14M are executed in a sequential manner. Next in Step S14M, the processing liquid flow rate adjustment section 130 adjusts the supply flow rate of the processing liquid LQ supplied from a processing liquid supply section An belonging to the M-th group GM to control behavior of the bubbles BB. In the manner described above, in Step S14, the supply flow rates of the processing liquid LQ supplied by the processing liquid supply sections An belonging to the respective groups are adjusted on a group-by-group basis in different periods that are mutually different for each of the groups.

In Step S15 by contrast, the bubble adjustment section 140 adjusts the supply flow rate of the gas GA for generating the bubbles BB for each of the bubble supply pipes 1 in response to supply of the processing liquid LQ by the first group G1 to the M-th group GM.

Specifically, Step S15 includes Steps S151, S152, S153, S154, . . . , and S15M. First in Step S151, the bubble adjustment section 140 adjusts the supply flow rate of the gas GA in response to supply of the processing liquid LQ from the processing liquid supply section An belonging to the first group G1. Next in Step S152, the bubble adjustment section 140 adjusts the supply flow rate of the gas GA in response to supply of the processing liquid LQ from the processing liquid supply section An belonging to the second group G2. Thereafter, Steps S153, S154, . . . , and S15M are executed in a sequential manner. In Step S15M, the bubble adjustment section 140 adjusts the supply flow rate of the gas GA in response to supply of the processing liquid LQ from the processing liquid supply section An belonging to the M-th group GM. In the manner described above, the supply flow rate of the gas GA is adjusted in response to supply of the processing liquid LQ by each group in Step S15.

Next in Step S16, all of the processing liquid supply sections An start supply of the processing liquid LQ toward the processing liquid LQ stored in the processing tank 110.

Next in Step S17, the substrate holding section 120 pulls the substrates W out of the processing liquid LQ. The substrate processing method ends then.

### (Second Variation)

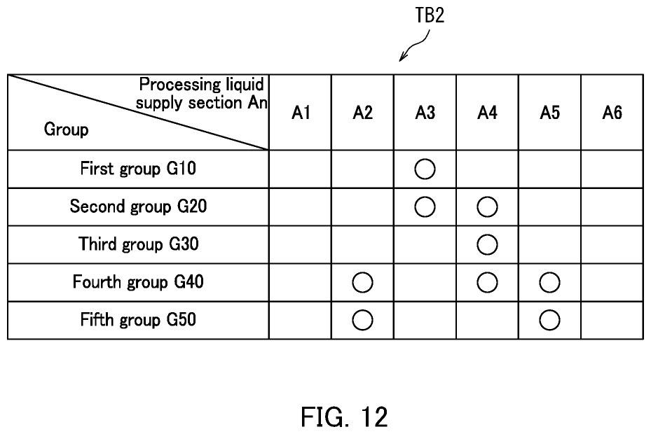

With reference to FIGS. 1 and 12, a second variation of the first embodiment is described. The second variation mainly differs from the first embodiment in that a processing liquid supply section An is provided that belongs to a plurality of groups. The following mainly describes difference of the second variation from the first embodiment.

In the second variation, a first group G10, a second group G20, a third group G30, a fourth group G40, and a fifth group G50 are set in the substrate processing apparatus 100 as one example.

FIG. 12 indicates Table TB2 that defines the first group G10 to the fifth group G50 of the processing liquid supply sections An. As indicated in Table TB2 in FIG. 12, the first group G10 includes only the first processing liquid supply section A3. The second group G20 includes the first processing liquid supply section A3 and the second processing liquid supply section A4. The third group G30 includes only the second processing liquid supply section A4.

The first processing liquid supply section A3 belonging to the first group G10 and the second processing liquid supply section A4 belonging to the third group G30 also belong to the second group G20. In the above configuration in the second variation, supply stop of the processing liquid LQ can be avoided in transition from the first group G10 to the third group G30. As a result, smooth transition from the first group G10 to the third group G30 can be achieved.

The fourth group G40 includes the first processing liquid supply section A2, the second processing liquid supply section A4, and the second processing liquid supply section A5.

The fifth group G50 includes the first processing liquid supply section A2 and the second processing liquid supply section A5.

The second processing liquid supply section A4 belonging to the third group G30 and the first processing liquid supply section A2 and the second processing liquid supply section A5 each belonging to the fifth group G50 also belong to the fourth group G40. In the above configuration in the second variation, supply stop of the processing liquid LQ can be avoided in transition from the third group G30 to the fifth group G50. As a result, smooth transition from the third group G30 to the fifth group G50 can be achieved.

### (Third Variation)

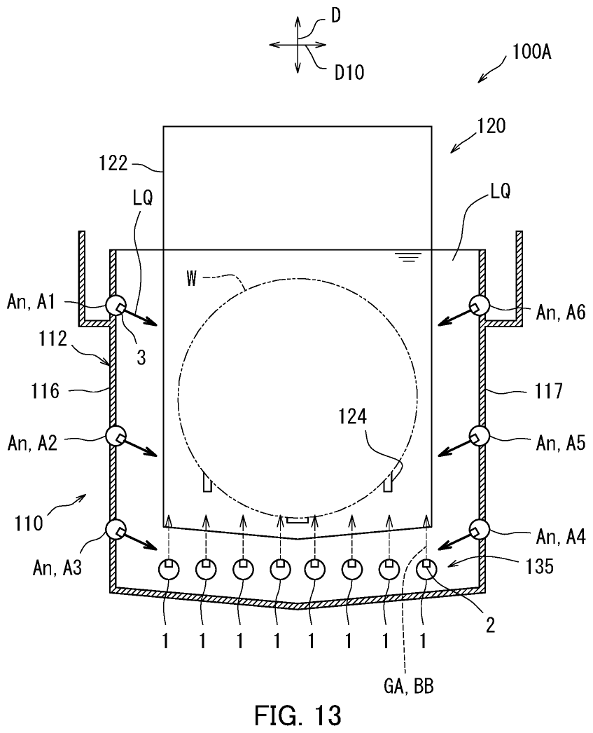

With reference to FIGS. 1 and 13, a third variation of the first embodiment is described. The third variation mainly differs from the first embodiment in inclusion of eight bubble supply pipes 1. The following mainly describes difference of the third variation from the first embodiment.

FIG. 13 is a schematic cross-sectional view of a substrate processing apparatus 100A according to the third variation. As illustrated in FIG. 13, a bubble supply section 135 of the substrate processing apparatus 100A includes eight bubble supply pipes 1. In the above configuration in the third variation, a larger amount of the bubbles BB can be supplied to the processing liquid LQ than a case in which the bubble supply section 135 includes less than eight bubble supply pipes 1. As a result, areas with an insufficient amount of the bubbles BB can be reduced on and around the surfaces of the substrates W. This can reduce the dissolved oxygen concentration in the processing liquid LQ over the entirety of each of the surfaces of the substrates W, thereby further reducing unevenness in processing with the processing liquid LQ in in-plane of each substrate W.

### (Fourth Variation)

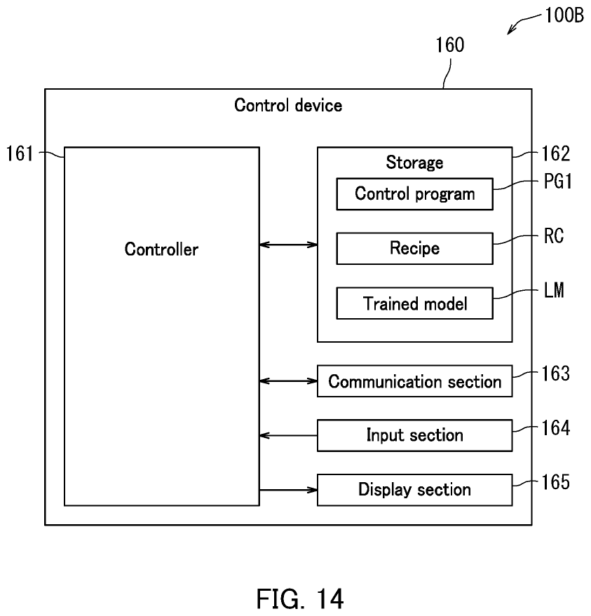

With reference to FIGS. 14 to 17, a fourth variation of the first embodiment is described. The fourth variation mainly differs from the first embodiment in execution of the substrate processing using a trained model LM generated through machine learning. The following mainly describes difference of the fourth variation from the first embodiment.

FIG. 14 is a block diagram illustrating a control device 160 of a substrate processing apparatus 100B according to the fourth variation of the first embodiment. As illustrated in FIG. 14, the control device 160 includes a communication section 163, an input section 164, and a display section 165 in addition to the controller 161 and the storage 162. The communication section 163 is connected to a network to communicate with external devices. Examples of the network include the Internet, local area networks (LANs), public telephone networks, and short-range wireless networks. The communication section 163 is a communicator such as a network interface controller.

The communication section 163 may include a wired communication module or a wireless communication module. The input section 164 is an input device for inputting various information to the processing section 161. For example, the input section 164 is a touch panel or a keyboard and a pointing device. The display section 165 displays images. Examples of the display section 165 include a liquid-crystal display and an organic electroluminescent display.

The storage 162 stores a control program PG1, recipe information RC, and a trained model LM therein. The controller 161 executes the control program PG1 to process substrates W with a processing liquid LQ according to the recipe information RC. The recipe information RC defines processing details and a processing procedure for the substrates W. Specifically, the controller 161 executes the control program PG1 to control the storage 162, the communication section 163, the input section 164, the display section 165, and each of a substrate holding section 120, a processing liquid flow rate adjustment section 130, a bubble adjustment section 140, and a drainage section 150 as illustrated in FIG. 1. The controller 161 also executes the control program PG1 to activate the trained model LM.

The trained model LM is constituted through training data (also referred to below as “training data DT”) learning.

The training data DT includes processing amount information IF1 and processing condition information IF2. The processing amount information IF1 is an explanatory variable. That is, the processing amount information IF1 is a feature amount. The processing condition information IF2 is a target variable.

The processing amount information IF1 includes information indicating a processing amount of a training substrate (also referred to below as “training substrate Wa”) for training with a training processing liquid. The training processing liquid in the fourth variation is a virtual processing liquid used in bubble behavior simulation and is used for training. Furthermore, the training substrate Wa is a virtual substrate in bubble behavior simulation and is used for training. Examples of the processing amount of the training substrate Wa include an etch rate of the training substrate Wa, an etching amount of the training substrate Wa, and the thickness of the training substrate Wa.

The processing condition information IF2 includes at least: information indicating at least one training processing liquid supply section in each of training groups; and information indicating timing of when each of the training groups supplies the training processing liquid. The training groups are virtual groups in bubble behavior simulation that correspond to the groups defined in the first embodiment, and are used for training. The training processing liquid supply sections are virtual processing liquid supply sections in bubble behavior simulation that correspond to the processing liquid supply sections An in the first embodiment, and are used for training. The training processing liquid supply sections supply the training processing liquid in bubble behavior simulation.

Of the training processing liquid supply sections, each of two or more training processing liquid supply sections belong to at least one training group among the training groups that are mutually different. The training groups are control units of the training processing liquid supply sections. In the above configuration, the training processing liquid supply sections are controlled in units of the training group in bubble behavior simulation.

One training processing liquid supply section may belong to one training group and one training processing liquid supply section may belong to a plurality of training groups. Each of the graining groups includes at least one training processing liquid supply section. In the above configuration, one training processing liquid supply section may belong to one training group and a plurality of training processing liquid supply sections may belong to one training group. Furthermore, some of the training processing liquid supply sections may not belong to any of the training groups. In this case, the training processing liquid supply section that belongs to none of the training groups is not used in bubble behavior simulation. In other words, only training processing liquid supply sections belonging to any of the training groups are used in bubble behavior simulation.

In bubble behavior simulation, the training processing liquid supply sections belonging to any of the training groups supply the training processing liquid toward bubbles for different periods that are mutually different for each of the groups.

The controller 161 inputs input information IF3 to the trained model LM to acquire output information IF4 from the trained model LM. The input information IF3 includes information indicating a target value of the processing amount of the substrates W that are to be processed with the processing liquid LQ. The processing amount of the substrates W indicates an etch rate of the substrates W, an etching amount of the substrates W, or the thickness of the substrates W.

The output information IF4 includes at least information indicating at least one processing liquid supply section An in each of groups and information indicating timing of when each of the groups is to supply the processing liquid LQ. The “timing” in this case includes the order of the groups and the implementation period for each of the groups.

In the fourth variation, the controller 161 controls the processing liquid supply sections An based on the output information IF4. Specifically, the controller 161 controls behavior of the bubbles BB using the processing liquid LQ by controlling each of the processing liquid supply sections An so as to reach the settings indicated in the output information IF4. In the above configuration, areas with an insufficient amount of the bubbles BB can be reduced in and around the surfaces of the substrates W. As a result, the dissolved oxygen concentration in the processing liquid LQ can be reduced over the entirety of each of the surfaces of the substrates W, thereby reducing unevenness in processing with the processing liquid LQ in the in-plane of each substrate W.

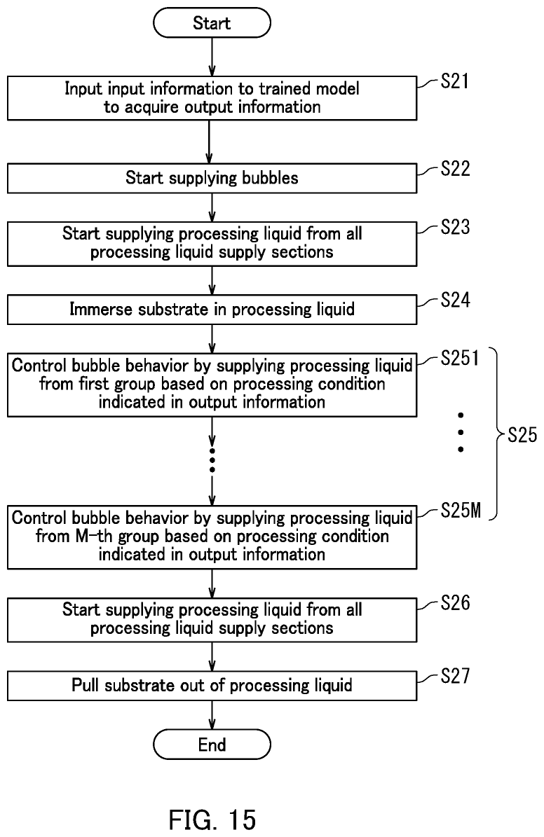

With reference to FIGS. 14 and 15, a substrate processing method according to the fourth variation is described next. FIG. 15 is a flowchart depicting the substrate processing method according to the fourth variation. The substrate processing method is implemented by the substrate processing apparatus 100B. As depicted in FIG. 15, the substrate processing method includes Steps S21 to S27. Steps S21 to S27 are executed under control of the controller 161.

First in Step S21, the controller 161 inputs the input information IF3 to the trained model LM and acquires the output information IF4 from the trained model LM as illustrated in FIGS. 14 and 15. Step S21 corresponds to one example of “using a trained model” in the present disclosure.

Steps S22 to S24 are the same as Steps S1 to S3 in FIG. 10, respectively, and description thereof is therefore omitted. After Step S24, the routine proceeds to Step S25.

Next in Step S25, the controller 161 controls the processing liquid supply sections An based on a processing condition (information indicating at least one processing liquid supply section An in each of the groups and information indicating timing of when each of the groups is to supply the processing liquid LQ) indicated in the output information IF4 that has been acquired in Step S21.

Specifically, Step S25 includes Steps S251, S252, S253, S254, . . . , and S25M. First in Step S251, the processing liquid LQ is supplied toward the bubbles BB from a processing liquid supply section An belonging to the first group G1 based on the processing condition indicated in the output information IF4. Next in Step S252, the processing liquid LQ is supplied toward the bubbles BB from a processing liquid supply section An belonging to the second group G2 based on the processing condition indicated in the output information IF4. Thereafter, Steps S253, S254, . . . , and S25M are executed in a sequential manner. In Step S25M, the processing liquid LQ is supplied toward the bubbles BB from a processing liquid supply section An belonging to the M-th group GM based on the processing condition indicated in the output information IF4. In the manner described above, the processing liquid supply sections An belonging to the respective group supply the processing liquid LQ toward the bubbles BB for different periods that are mutually different for each of the groups based on the processing condition indicated in the output information IF4 in Step S25.

Next in Step S26, all of the processing liquid supply sections An start supply of the processing liquid LQ toward the processing liquid LQ stored in the processing tank 110.

Next in Step S27, the substrate holding section 120 pulls the substrates W out of the processing liquid LQ. The substrate processing method ends then.

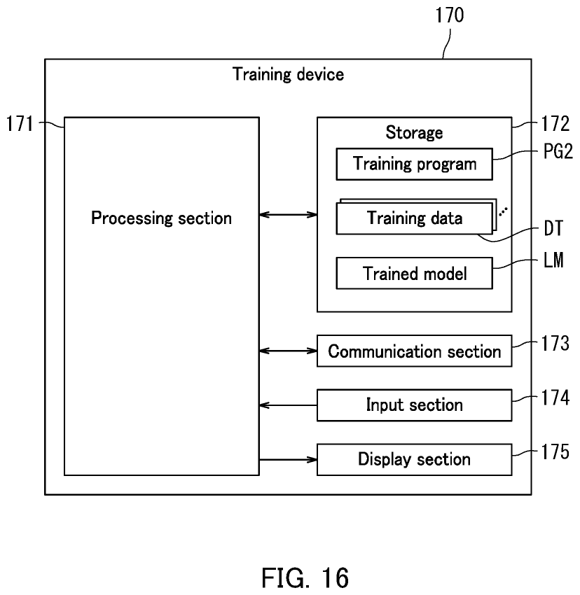

With reference to FIG. 16, a training device 170 according to the fourth variation is described next. The training device 170 is a computer, for example. FIG. 16 is a block diagram of the training device 170. As illustrated in FIG. 16, the training device 170 includes a processing section 171, storage 172, a communication section 173, an input section 174, and a display section 175.

The processing section 171 includes a processor such as a CPU or a GPU. The storage 172 includes a storage device and stores data and computer programs therein. The processor of the processing section 171 executes the computer programs stored in the storage device of the storage 172 to execute various processing. The storage 172 has the same hardware configuration as the storage 162 illustrated in FIG. 14.

The communication section 173 is connected to a network to communicate with external devices. The communication section 173 has the same hardware configuration as the communication section 163 illustrated in FIG. 14. The input section 174 is an input device for inputting various information to the processing section 171. The input section 174 has the same hardware configuration as the input section 164 illustrated in FIG. 14. The display section 175 displays images. The display section 175 has the same hardware configuration as the display section 165 illustrated in FIG. 14.

Continuing to refer to FIG. 16, the processing section 171 is described. The processing section 171 acquires multiple pieces of training data DT from the outside. For example, the processing section 171 acquires multiple pieces of training data DT from a simulation device or a training data generating device via the network and the communication section 173. The training data generating device generates the training data DT based on data acquired from the simulation device.

The processing section 171 controls the storage 172 to store each piece of the training data DT. As a result, the storage 172 stores each piece of the training data DT.

The storage 172 stores a training program PG2 therein. The training program PG2 is a program for finding out a certain rule from among the multiple pieces of training data DT and executing a machine learning algorithm for generating a trained model LM that expresses the found rule.

The machine learning algorithm is not limited particularly and may be a decision tree, a nearest neighbor method, a naive bayes classifier, a support vector machine, or a neural network, for example. As such, the trained model LM includes a decision tree, a nearest neighbor method, a naive bayes classifier, a support vector machine, or a neural network. In machine learning for generating the trained model LM, error backpropagation may be used.

For example, the neural network includes an input layer, a single or plurality of intermediate layers, and an output layer. Specifically, the neural network is a deep neural network (DNN), a recurrent neural network (RNN), or a convolutional neural network CNN), and performs deep learning. For example, the deep neural network includes an input layer, a plurality of intermediate layers, and an output layer. The processing section 171 performs machine learning of the multiple pieces of training data DT based on the training program PG2. As a result, a certain rule is found out from among the multiple pieces of the training data DT, thereby generating a trained model LM. That is, the trained model LM is constituted through machine learning of the training data DT. The storage 172 stores the trained model LM therein.

Specifically, the processing section 171 generates the trained model LM through execution of the training program PG2 for finding out a certain rule between the explanatory variable and the target variable each included in the training data DT.

More specifically, through machine learning of multiple pieces of the training data DT based on the training program PG2, the processing section 171 calculates a plurality of trained parameters and generates the trained model LM including at least one function to which the trained parameters are applied. The trained parameters are parameters (coefficients) acquired based on a result of machine learning using the multiple pieces of training data DT.

The trained model LM causes the computer to function to input the input information IF3 and output the output information IF4. In other words, the trained model LM inputs the input information IF3 and outputs the output information IF4. Specifically, the trained model LM estimates a processing condition that makes the processing amounts of processing with the processing liquid LQ even in the in-plane of each substrate W. The processing condition includes at least information indicating at least one processing liquid supply section An in each of the groups and information indicating timing of when each of the groups is to supply the processing liquid LQ.

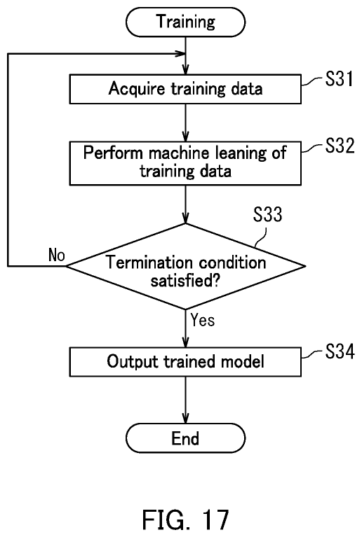

With reference to FIGS. 16 and 17, a training method according to the fourth variation is described next. FIG. 17 is a flowchart depicting the training method according to the fourth variation. As depicted in FIG. 17, the training method includes Steps S31 to S34. The training method is implemented by the training device 170.

In step S31, the processing section 171 of the training device 170 acquires multiple pieces of training data DT from the simulation device or the training data generating device as illustrated in FIGS. 16 and 17.

Next in Step S32, the processing section 171 performs machine learning of the multiple pieces of training data DT based on the training program PG2.

Next in Step S33, the processing section 171 determines whether or not a learning termination condition is satisfied. The learning termination condition is a condition predetermined for terminating the machine learning. The learning termination condition is that the number of repetitions reaches a specific number of times, for example.

If a negative determination is made in Step S33, the routine returns to Step S31. As a result, the machine learning is repeated.

If an affirmative determination is made in Step S33 by contrast, the routine proceeds to Step S34.

In Step S34, the processing section 171 outputs as a trained model LM a plurality of latest parameters (coefficients), that is, a model (at least one function) to which a plurality of trained parameters (coefficients) are applied. The storage 172 stores the trained model LM then.

In the manner described above, execution of Steps S31 to S34 by the training device 170 generates the trained model LM.

That is, the training device 170 performs machine learning in the fourth variation. As a result, a highly accurate trained model LM can be generated by finding regularity from the training data DT which is extremely complex and which includes a huge amount of analysis targets. The controller 161 of the control device 160 illustrated in FIG. 14 inputs the input information IF3 including the target value for the processing amount to the trained model LM and causes the trained model LM to output the output information IF4 including the information about the processing condition. In the above configuration, setting of each processing liquid supply section An can be quickly done to increase throughput in processing of the substrates W.

Note that the control device 160 in FIG. 14 may act as the training device 170 in FIG. 16.

With reference to FIG. 9A, a method for generating the training data DT is described next in detail. The following describes an example in which a simulation device that executes bubble behavior simulation generates the training data DT. Furthermore, the substrate W illustrated in FIG. 9A is regarded as a “training substrate Wa” in the following description.

First, processing condition information Q2 is input to the simulation device. The processing condition information Q2 includes at least information indicating at least: one training processing liquid supply section in each of the training groups; and information indicating timing of when each of the training groups supplies the training processing liquid.

Next, the simulation device performs bubble behavior simulation based on the processing condition information Q2. As a result, the simulation device outputs a simulation result indicating a bubble distribution.

Specifically, the following simulation result is output. That is, areas 16 each with four monitoring points 12 as apexes are set in the training substrate Wa illustrated in FIG. 9A. As a result, a plurality of areas 16 are set in the training substrate Wa. In the example illustrated in FIG. 9A, the areas 16 are square in shape. Furthermore, one monitoring point 12 is associated with one area 16. For example, a monitoring point 12 located at the lower right corner of the square of one of the areas 16 is associated with one of the areas 16. The cumulative value of the numbers of bubbles passing over the monitoring point 12 is treated as a cumulative value of the numbers of bubbles passing over the area 16 associated with the monitoring point 12. That is, the cumulative value of the numbers of passing bubbles is assigned to each of the areas 16. In the above configuration, the simulation device outputs the cumulative value of the numbers of passing bubbles in each of the areas 16 as a simulation result.

Next, the simulation device converts the cumulative value of the numbers of passing bubbles to a processing amount of the training substrate Wa processed with the training processing liquid for each of the areas 16 using a conversion function or a conversion table. As a result, a processing amount is obtained for each of the areas 16 of the training substrate Wa. That is, processing amount information Q1 is acquired that indicates a processing amount distribution in the in-plane of the training substrate Wa. In other words, the processing amount information Q1 is information indicating a processing amount for each of the areas 16 of the training substrate Wa processed with the training processing liquid. The processing amount indicates for example an etch rate of each of the areas 16 of the training substrate Wa, an etching amount of each of the areas 16 of the training substrate Wa, or the thickness of each of the areas 16 of the training substrate Wa.

Note that since a positive correlation (e.g., a directly proportional relationship) is present between the processing amount and the amount of bubbles (see FIGS. 3 and 4), the conversion function or the conversion table is pre-derived experimentally.

Here, many simulation results can be obtained by inputting various processing condition information Q2 to the simulation device. Many pieces of processing amount information Q1 are obtained from the many simulation results.

The simulation device acquires, from among the many pieces of processing amount information Q1, processing amount information Q1 where variation in the processing amount for each of the areas 16 is within a predetermined range and processing condition information Q2 corresponding to the processing amount information Q1 as the processing amount information IF1 and the processing condition information IF2 of the training data DT, respectively. For example, the simulation device acquires, from among the many pieces of processing amount information Q1, processing amount information Q1 where the standard deviation or dispersion of the processing amount for each of the areas 16 is no greater than a threshold value and processing amount information Q1 corresponding to the processing condition information Q2 as the processing amount information IF1 and the processing condition information IF2 of the training data DT, respectively.

Thereafter, the training device 170 illustrated in FIG. 16 acquires many pieces of training data DT from the simulation device and learns the many pieces of training data DT. Note that it is possible that the training data generating device acquires the simulation result from the simulation device to generate the training data DT based on the simulation result.

As described so far with reference to FIGS. 9A and 16, the trained model LM is generated through learning the training data DT including the processing amount information IF1 where variation in processing amount in the in-plane of the training substrate Wa is small in the fourth variation. In the above configuration, control of each of the processing liquid supply sections An based on the output information IF4 acquired by inputting the input information IF3 to the trained model LM can achieve effective reduction in variation in processing amount in the in-plane of each substrate W.

In detail, the input information IF3 herein includes information indicating a target value of the processing amount for each of the areas 15 of the substrates W to be processed with the processing liquid LQ. The areas 15 of the substrates W correspond to the areas 16 of the training substrate Wa. The processing amount indicates for example an etch rate of each of the areas 15 of the substrates W, an etching amount of each of the areas 15 of the substrates W, or the thickness of each of the areas 15 of the substrates W.

The target values of the processing amount in the areas 15 of the substrates W are set to the same value in the input information IF3. This is to reduce variation among the processing amounts in the in-plane of each of the substrates W. Alternatively, the target values of the processing amount in the input information IF3 may have a width defined with an upper limit and a lower limit.

The output information IF4 includes at least information indicating at least one processing liquid supply section An in each of the groups and information indicating timing of when each of the groups is to supply the processing liquid LQ. In this case, the “timing” includes the order of the groups and the implementation period for each of the groups.

Note that the processing amount information IF1 and the processing amount information Q1 may each be a cumulative value of the numbers of passing bubbles in each of the areas 16 of the training substrate Wa. In this case, the input information IF3 indicates a target value of the cumulative value of the numbers of passing bubbles BB in each of the areas 15 of the substrate W.

The processing condition information IF2 and the processing condition information Q2 may each include information about the flow rate of the training processing liquid from each training processing liquid supply section. In this case, the output information IF4 includes information about the flow rate of the processing liquid LQ from each of the processing liquid supply sections An.

Furthermore, the processing condition information IF2 and the processing condition information Q2 may each include information about at least one of the type, concentration, and temperature of the training processing liquid. In this case, the output information IF4 includes information about at least one of the type, concentration, and temperature of the processing liquid LQ.

Moreover, the processing condition information IF2 and the processing condition information Q2 may each include information about at least one of the diameter, thickness, and contact angle of the training substrate Wa. In this case, the output information IF4 includes information about at least one of the diameter, thickness, and contact angle of the substrate W.

In addition, the processing condition information IF2 and the processing condition information Q2 may each include information about at least one of the flow rate of a training gas to be supplied to training bubble supply pipes, the intervals between training bubble holes in the training bubble supply pipes, and the specification of the training bubble supply pipes. In this case, the output information IF4 includes information about at least one of the flow rate of the gas GA to be supplied to the bubble supply pipes 1, the intervals between the bubble holes 2 in the bubble supply pipes 1, and the specification of the bubble supply pipes 1.

Note that in bubble behavior simulation, the training bubble supply pipes are virtual bubble supply pipes corresponding to the bubble supply pipes 1 in the above-described first embodiment and are used for training. In bubble behavior simulation, the training gas and the training bubble holes are respectively a virtual gas corresponding to the gas GA and virtual bubble holes corresponding to the bubble hoes 2 in the above-described first embodiment, and are used for training.

### (Fifth Variation)

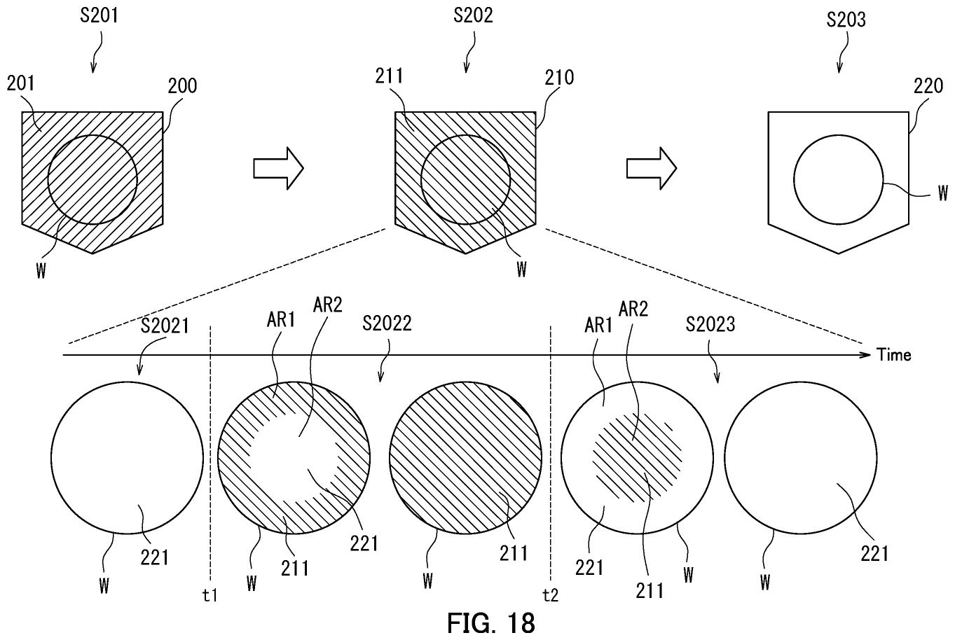

With reference to FIGS. 18 to 20, a fifth variation of the first embodiment is described. In the fifth variation, a rinse liquid is used as the processing liquid LQ. The following mainly describes difference of the fifth variation from the first embodiment.

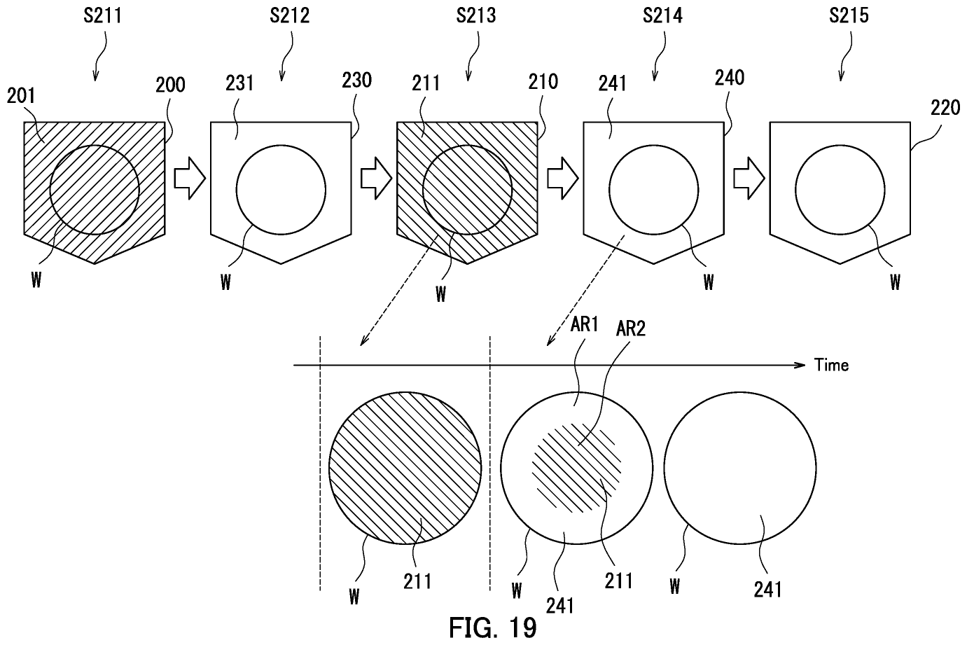

With reference to a first reference example in FIG. 18 and a second reference example in FIG. 19, a tendency is described first when a chemical liquid on the substrate W is replaced with the rinse liquid. In the fifth variation, the first reference example, and the second reference example, a substrate W includes a silicon substrate and a pattern. The silicon substrate is substantially disc-shaped. The pattern is formed on the silicon substrate. The pattern includes a layered film. The layered film includes a plurality of polysilicon films and a plurality of silicon oxide films. The polysilicon films and the silicon oxide films are alternately layered in the thickness direction of the substrate W. The thickness direction is a direction substantially perpendicular to the surface of the silicon substrate. BHF is used as a first chemical liquid 201 and TMAH is used as a second chemical liquid 211. Note that the second chemical liquid 211 may include TMAH and IPA. As a result of including IPA, the second chemical liquid 211 easily permeates the recesses of the pattern of the substrate W even when the recesses of the pattern is minute.

With reference to FIG. 18, the first reference example is described first. FIG. 18 is a diagram illustrating a substrate processing method according to the first reference example in replacement of the second chemical liquid 211 with the rinse liquid 221. In the first reference example, chemical liquid processing with the second chemical liquid 211 and rinsing processing with the rinse liquid 221 are performed in the same tank (second chemical liquid tank 210).

As illustrated in FIG. 18, the substrate processing method according to the first reference example includes Steps S201 to S203.

First in Step S201, the substrate W is immersed in the first chemical liquid 201 in the first chemical liquid tank 200 to etch the substrate W with the first chemical liquid 201. Specifically, one or more recesses are formed in the layered film of the substrate W with the first chemical liquid 201. The recesses are trenches or holes, for example. The polysilicon films and the silicon oxide films are exposed in each recess. After etching in the first chemical liquid tank 200, the substrate W is pulled out of the first chemical liquid tank 200 and transported to the second chemical liquid tank 210.

Next in Step S202, the substrate W is immersed in the second chemical liquid 211 in the second chemical liquid tank 210 to etch the substrate W with the second chemical liquid 211. Specifically, the polysilicon films in the recesses formed in the layered film of the substrate W are etched with the second chemical liquid 211. More specifically, the polysilicon films in the recess of the substrate W with the second chemical liquid 211 are etched in a direction substantially perpendicular to the thickness direction of the substrate W.

In detail, Step S202 using the second chemical liquid tank 210 includes Steps S2021 to S2023.

First in Step S2021, the rinse liquid 221 is stored in the second chemical liquid tank 210. The substrate W is then immersed in the rinse liquid 221 in the second chemical liquid tank 210 to be rinsed with the rinse liquid 221.

Next in step S2022, the second chemical liquid 211 is supplied to the second chemical liquid tank 210 storing the rinse liquid 221. In the example illustrated in FIG. 18, supply of the second chemical liquid 211 to the second chemical liquid tank 210 storing the rinse liquid 221 starts. As a result, the rinse liquid 221 in the second chemical liquid tank 210 is gradually replaced with the second chemical liquid 211. Thus, the substrate W is etched with the second chemical liquid 211.

In this case, replacement of the rinse liquid 221 with the second chemical liquid 211 on the substrate W proceeds from the outer periphery of the substrate W toward the center of the substrate W. As such, replacement with the second chemical liquid 211 proceeds faster in an outer region AR1 than in an inner region AR2 of the substrate W in the in-plane of the substrate W. As a result, the etching amount in the outer region AR1 may be larger than the etching amount in the inner region AR2 in some cases. In other words, the etching amount in the inner region AR2 may be smaller than the etching amount in the outer region AR1 in some cases.

Thereafter, the rinse liquid 221 is replaced with the second chemical liquid 211 also in the inner region AR2. As a result, the entire in-plane of the substrate W is etched with the second chemical liquid 211.

Next in Step S2023, the rinse liquid 221 is supplied to the second chemical liquid tank 210 storing the second chemical liquid 211. In the example illustrated in FIG. 18, supply of the rinse liquid 221 to the second chemical liquid tank 210 storing the second chemical liquid 211 starts at time t2. As a result, the second chemical liquid 211 in the second chemical liquid tank 210 is gradually replaced with the rinse liquid 221. Thus, the substrate W is rinsed with the rinse liquid 221.

In this case, replacement of the second chemical liquid 211 with the rinse liquid 221 on the substrate W proceeds from the outer periphery of the substrate W toward the center of the substrate W. As such, replacement of the second chemical liquid 211 with the rinse liquid 221 proceeds faster in the outer region AR1 than in the inner region AR2 of the substrate W in the in-plane of the substrate W. As a result, the inner region AR2 may be etched with the second chemical liquid 211 remaining in the inner region AR2.

Thereafter, the second chemical liquid 211 is replaced with the rinse liquid 221 also in the inner region AR2. As a result, the entire in-plane of the substrate W is rinsed with the rinse liquid 221.

In the chemical liquid processing in Step S2022, the etching amount in the inner region AR2 of the substrate W may be smaller than the etching amount in the outer region AR1 thereof. In the rinsing processing in Step S2023 by contrast, the inner region AR2 may be etched. As a result, etching in Step S2022 and etching in Step S2023 fall in a complementary relationship. That is, the inner region AR2 with less etching amount in Step S2022 is etched with the remaining second chemical liquid 211 in Step S2023. As such, the etching amount is even over the entire in-plane of the substrate W in Step S202.

The substrate W etched with the second chemical liquid 211 is pulled out of the second chemical liquid tank 210 and transported to a drying tank 220 after being rinsed in the second chemical liquid tank 210.

Next in Step S203, the substrate W is dried in the drying tank 220. The substrate processing method according to the first reference example ends then.

As has been described with reference to FIG. 18, the rinsing processing and the chemical liquid processing are performed in the same tank (second chemical liquid tank 210) in the first reference example. Accordingly, each time processing for one lot of substrates W (e.g., 25 or 50 substrates W) is completed, the rinse liquid 221 and the second chemical liquid 211 must be discarded. In view of the foregoing, the rinsing processing and the chemical liquid processing are performed in different tanks in order to reuse the rinse liquid 221 and the second chemical liquid 211 for a plurality of lots.

The second reference example is described next with reference to FIG. 19. FIG. 19 is a diagram illustrating a substrate processing method according to the second reference example in replacement of the second chemical liquid 211 with the rinse liquid 221. In the second reference example, the chemical liquid processing with the second chemical liquid 211 and the rinsing processing with a rinse liquid 241 are performed in different tanks (the second chemical liquid tank 210 and a second rinse tank 240).

As illustrated in FIG. 19, the substrate processing method according to the second reference example includes Steps S211 to S215.

Next in Step S211, a substrate W is immersed in the first chemical liquid 201 in the first chemical liquid tank 200 to be etched with the first chemical liquid 201. This is the same as Step S201 in FIG. 18. After etching in the first chemical liquid tank 200, the substrate W is pulled out of the first chemical liquid tank 200 and transported to the first rinse tank 230.

Next in Step S212, the substrate W is immersed in the rinse liquid 231 in the first rinse tank 230 to be rinsed with the rinse liquid 231. After rising in the first rinse tank 230, the substrate W is pulled out of the first rinse tank 230 and transported to the second chemical liquid tank 210.

Next in Step S213, the substrate W is immersed in the second chemical liquid 211 in the second chemical liquid tank 210 to be etched with the second chemical liquid 211. This is the same as Step S202 in FIG. 18. However, the rinsing processing is not performed in the second chemical liquid tank 210 in Step S213. That is, the second chemical liquid tank 210 does not store any rinse liquids and stores only the second chemical liquid 211. As such, the etching amount is even over the entire in-plane of the substrate W in Step S213. After etching with the second chemical liquid 211 in the second chemical liquid tank 210, the substrate W is pulled out of the second chemical liquid tank 210 and transported to the second rinse tank 240.

Next in Step S214, the substrate W is immersed in the rinse liquid 241 in the second rinse tank 240 to be rinsed with the rinse liquid 241.

Specifically, replacement of the second chemical liquid 211 with the rinse liquid 241 on the substrate W immersed in the rinse liquid 241 proceeds from the outer periphery of the substrate W toward the center of the substrate W. As such, replacement of the second chemical liquid 211 with the rinse liquid 241 proceeds faster in the outer region AR1 than in the inner region AR2 in the in-plane of the substrate W. As a result, the inner region AR2 may be etched with the second chemical liquid 211 remaining in the inner region AR2.

Thereafter, the second chemical liquid 211 is replaced with the rinse liquid 241 also in the inner region AR2. As a result, the entire in-plane of the substrate W is rinsed with the rinse liquid 241.

After rinsing with the rinse liquid 241 in the second rinse tank 240, the substrate W is pulled out of the second rinse tank 240 and transported to the drying tank 220.

Next in Step S215, the substrate W is dried in the drying tank 220. The substrate processing method according to the second reference example ends then.

As has been described with reference to FIG. 19, the inner region AR2 of the substrate W may be etched with the remaining second chemical liquid 211 in Step S214. Therefore, the etching amount may not be even in the in-plane of the substrate W. That is, unevenness in etching amount may occur in the in-plane of the substrate W.

In particular, the shorter the etching time with the second chemical liquid 211 is, the more significant the influence of the remains of the second chemical liquid 211 in the second rinse tank 240 is. This is because a shorter etching time indicates higher etch rate and therefore etching proceeds with the second chemical liquid 211 remaining on the substrate W in the second rinse tank 240.

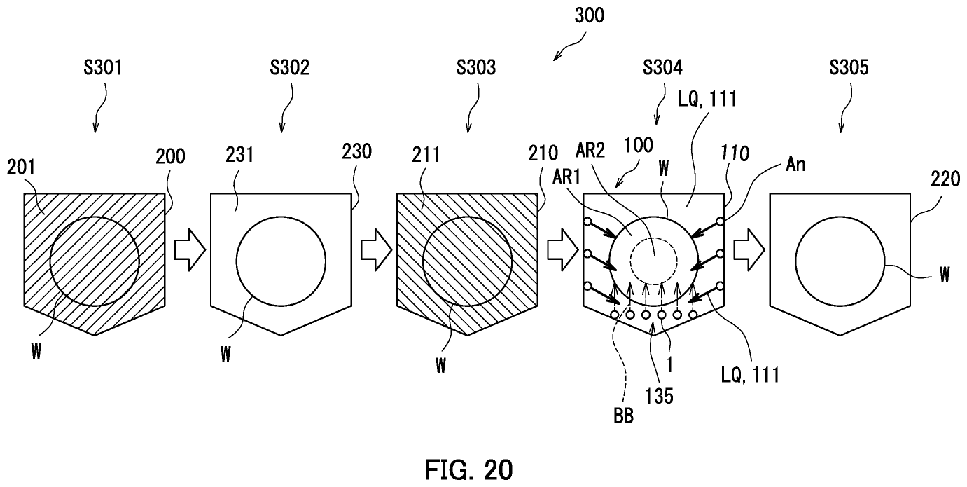

In view of the foregoing, a substrate processing apparatus 300 (FIG. 20) according to the fifth variation of the first embodiment includes a processing tank 110 and the peripheral members as in FIG. 1 in place of the second rinse tank 240 in FIG. 19 in order to make the etching amount even over the entire in-plane of the substrate W.

FIG. 20 is a diagram illustrating a substrate processing method implemented by the substrate processing apparatus 300 according to the fifth variation of the first embodiment. As illustrated in FIG. 20, the substrate processing apparatus 300 includes a first chemical liquid tank 200, a first rinse tank 230, a second chemical liquid tank 210, a drying tank 220, and a processing tank 110 and peripheral members as in FIG. 1. The peripheral members of the processing tank 110 include processing liquid supply sections An and a bubble supply section 135. The bubble supply section 135 includes a plurality of bubble supply pipes 1.

In the fifth variation, a rinse liquid is stored in the processing tank 110 as the processing liquid LQ. That is, the processing liquid LQ is a rinse liquid. In the following, the rinse liquid is referred to as “rinse liquid 111” in the fifth variation. The first chemical liquid tank 200, the first rinse tank 230, the second chemical liquid tank 210, and the drying tank 220 are respectively the same as the first chemical liquid tank 200, the first rinse tank 230, the second chemical liquid tank 210, and the drying tank 220 in the second reference example in FIG. 19. Therefore, description thereof is omitted.

The substrate processing method implemented by the substrate processing apparatus 300 includes Steps S301 to S305. Steps S301, S302, S303, and S305 are respectively the same as Steps S211, S212, S213, and S215 in in the second reference example illustrated in FIG. 19. Therefore, description thereof is omitted.

In Step S303, the substrate W is pulled out of the second chemical liquid tank 210 and transported to the processing tank 110 after etching with the second chemical liquid 211 in the second chemical liquid tank 210 (i.e., after processing with the second chemical liquid 211).

Next in Step S304, the substrate W is immersed in the rinse liquid 111 in the processing tank 110 to be rinsed with the rinse liquid 111.

Specifically, as illustrated in FIGS. 1 and 20, the substrate holding section 120 immerses, in the rinse liquid 111 stored in the processing tank 110, the substrate W after processing with the second chemical liquid 211 stored in the second chemical liquid tank 210 different from the processing tank 110. In the fifth variation, the processing with the second chemical liquid 211 is etching with the second chemical liquid 211. The second chemical liquid tank 210 corresponds to an example of a “chemical liquid tank” in the present disclosure. The second chemical liquid 211 corresponds to an example of a “chemical liquid” in the present disclosure.

The bubble supply section 135 (bubble supply pipes 1) supplies bubbles BB to the rinse liquid 111 from below the substrate W. Behavior of the bubbles BB is controlled through supply of the rinse liquid 111 toward the bubbles BB from at least one of the processing liquid supply sections An. As a result, the distribution of the amount of the bubbles BB on and around the surfaces of the substrates W can be prevented from being skewed. In other words, areas with an insufficient amount of the bubbles BB can be reduced in and around the surfaces of the substrates W.

The bubbles BB (many bubbles BB) facilitate replacement of the second chemical liquid 211 with the rinse liquid 111 on the substrate W. As such, the second chemical liquid 211 is quickly replaced with the rinse liquid 111 even in the inner region AR2, in which the second chemical liquid 211 tends to remain more than in the outer region AR1 of the substrate W in the fifth variation. As a result, the processing amount (e.g., the etching amount) can become substantially even over the entire in-plane of the substrate W compared with a case in which the bubbles BB are not supplied (e.g., the second reference example illustrated in FIG. 19). That is, occurrence of unevenness in processing amount (e.g., the etching amount) in the entire in-plane of the substrate W can be inhibited. In particular, the speed of replacement of the second chemical liquid 211 with the rinse liquid 111 can be increased in the entire in-plane of substrate W in presence of the bubbles BB (many bubbles BB) compared with a case in which the bubbles BB are not supplied. That is, throughput of the rinsing processing can be increased.

One of the reasons why the bubbles BB facilitate replacement of the second chemical liquid 211 with the rinse liquid 111 on the substrate W (the surface of the substrate W) is thought to be that, for example, a turbulent flow is generated on the surface of the substrate W by the updraft of the bubbles BB, so that the second chemical liquid 211 on the surface of the substrate W is easily replaced with the rinse liquid 111. In other words, the updraft of the bubbles BB generates a turbulent flow on the surface of the substrate W to inhibit the second chemical liquid 211 and the rinse liquid 111 from stagnating on the surface of the substrate W. In other words, the updraft of the bubbles BB allows effective supply of fresh rinse liquid 111 to the surface of the substrate W.

Furthermore, in the fifth variation, the following is thought to be one of the reasons why occurrence of unevenness in processing amount (e.g., the etching amount) can be inhibited in the in-plane of the substrate W. That is, non-uniform flow in the processing tank 110 by the rinse liquid 111 supplied from the processing liquid supply sections An is rectified by the updraft of the bubbles BB. As a result, efficiency of replacement of the second chemical liquid 211 with the rinse liquid 111 is thought be equalized between in the outer region AR1 and in the inner region AR2 of the substrate W. Thus, occurrence of unevenness in processing amount in the in-plane of the substrate W can be inhibited.

Note that when the bubbles BB are not supplied, for example, the rinse liquid 111 may flow more easily in the outer region AR1 than in the inner region AR2 of the substrate W in presence of the flow in the processing tank 110 resulting from supply of the rinse liquid 111 from the processing liquid supply sections An. Therefore, when the bubbles BB are not supplied, the second chemical liquid 211 and the rinse liquid 111 are likely to stagnate in the inner region AR2 of the substrate W. In view of the foregoing, in the fifth variation, non-uniform flow in the processing tank 110 by the rinse liquid 111 supplied from the processing liquid supply sections An is rectified by the updraft of the bubbles BB through supply of the bubbles BB. As a result, efficiency of replacement of the second chemical liquid 211 with the rinse liquid 111 is thought to be equalized between in the outer region AR1 and in the inner region AR2 of the substrate W.

Furthermore, in the fifth variation, the rinsing processing with the rinse liquid 231 is performed in the first rinse tank 230, the chemical liquid processing with the second chemical liquid 211 is performed in the second chemical liquid tank 210, and the rinsing processing with the rinse liquid 111 is performed in the processing tank 110. That is, each rinsing processing and the chemical liquid processing are performed in different tanks. As such, it is not necessary to replace the rinse liquids 231 and 111 and the second chemical liquid 211 for each lot. As a result, the amounts of use of the rinse liquids 231 and 111 and the second chemical liquid 211 can be reduced compared with the case in the first reference example (FIG. 18). In other words, the rinse liquids 231 and 111 and the second chemical liquid 211 can be reused. Therefore, the amounts of waste of the rinse liquids 231 and 111 and the second chemical liquid 211 can be reduced.

### Second Embodiment

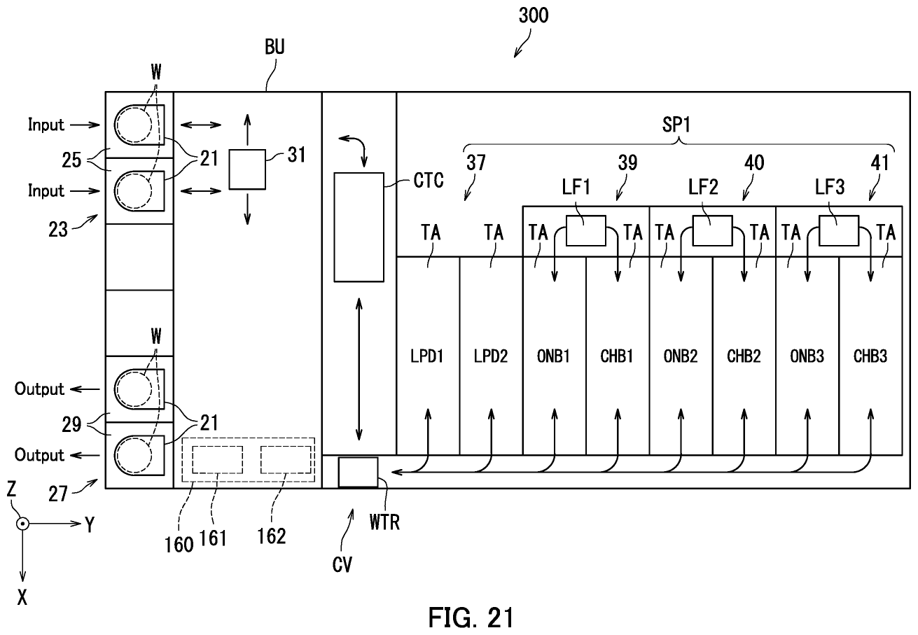

With reference to FIGS. 21 to 25, a substrate processing apparatus 300 according to a second embodiment of the present disclosure is described. The substrate processing apparatus 300 according to the second embodiment includes a fluid supply section 155 and a fluid adjustment section 145 in place of the bubble supply section 135 and the bubble adjustment section 140 in FIG. 1. The following mainly describes difference of the second embodiment from the first embodiment.

FIG. 21 is a schematic plan view of the substrate processing apparatus 300 according to the second embodiment. The substrate processing apparatus 300 processes a plurality of lots. Each of the lots is constituted by a plurality of substrates W. As illustrated in FIG. 21, the substrate processing apparatus 300 includes a plurality of accommodation sections 21, an input section 23, an output section 27, a delivery mechanism 31, a buffer unit BU, a transport mechanism CV, a processing section SP1, and a control device 160. The control device 160 (a controller 161) controls the accommodation sections 21, the input section 23, the output section 27, the delivery mechanism 31, the buffer unit BU, the transport mechanism CV, and the processing section SP1. The processing section SP1 includes a plurality of tanks TA. The transport mechanism CV includes a first transport mechanism CTC, a second transport mechanism WTR, a sub-transport mechanism LF1, a sub-transport mechanism LF2, and a sub-transport mechanism LF3.

The processing section SP1 includes a drying processing section 37, a first processing section 39, a second processing section 40, and a third processing section 41. The drying processing section 37 includes a tank LPD1 and a tank LPD2 among the tanks TA. The first processing section 39 includes a tank ONB1 and a tank CHB1 among the tanks TA. The second processing section 40 includes a tank ONB2 and a tank CHB2 among the tanks TA. The third processing section 41 includes a tank ONB3 and a tank CHB3 among the tanks TA.

Each of the accommodation sections 21 accommodates a plurality of substrates W. Each of the substrates W are accommodated in a horizontal posture in the accommodation sections 21. The accommodation sections 21 each may be a front opening unified pot (FOUP), for example.

Accommodation sections 21 that accommodate unprocessed substrates W are placed in the input section 23. Specifically, the input section 23 includes a plurality of placement tables 25. Two of the accommodation sections 21 are placed on two of the placement tables 25. The input section 23 is disposed in one end of the substrate processing apparatus 300 in the longitudinal direction thereof.

Accommodation sections 21 that accommodate processed substrates W are placed in the output section 27. Specifically, the output section 27 includes a plurality of placement tables 29. Two of the accommodation sections 21 are placed on two of the placement tables 29. The output section 27 accommodates the processed substrates W in the accommodation sections 21 and outputs them together with the accommodation sections 21. The output section 27 is disposed in the one end of the substrate processing apparatus 300 in the longitudinal direction thereof. The output section 27 is opposite to the input section 23 in a direction perpendicular to the longitudinal direction of the substrate processing apparatus 300.

The buffer unit BU is disposed adjacent to the input section 23 and the output section 27. The buffer unit BU catches thereinto an accommodation section 21 placed on the input section 23 together with the substrates W, and places the accommodation section 21 on a shelf (not illustrated). Furthermore, the buffer unit BU receives the processed substrates W, accommodates them in an accommodation section 21, and places the accommodation section 21 on the shelf. The delivery mechanism 31 is disposed in the buffer unit BU.

The delivery mechanism 31 performs delivery of an accommodation section 21 between the shelf and the input section 23 or the output section 27. The delivery mechanism 31 also performs deliver of only the substrates W between the delivery mechanism 31 and the transport mechanism CV. Specifically, the delivery mechanism 31 performs lot delivery between the delivery mechanism 31 and the transport mechanism CV. The transport mechanism CV performs lot transport into and out of the processing section SP1. Specifically, the transport mechanism CV performs lot transport into and out of each of the tanks TA of the processing section SP1. The processing section SP1 processes each substrate W in a lot.

Specifically, the delivery mechanism 31 performs lot delivery between the delivery mechanism 31 and the first transport mechanism CTC of the transport mechanism CV. The first transport mechanism CTC changes the posture of the substrates W in a lot received from the delivery mechanism 31 from the horizontal posture to the vertical posture, and then delivers the lot to the second transport mechanism WTR. The first transport mechanism CTC having received a processed lot from the second transport mechanism WTR changes the posture of the substrates W in the lot from the vertical posture to the horizontal posture, and then delivers the lot to the delivery mechanism 31.

The second transport mechanism WTR moves from the drying processing section 37 to the third processing section 41 of the processing section SP1 in the longitudinal direction of the substrate processing apparatus 300. In the above configuration, the second transport mechanism WTR transports a lot into and out of the drying processing section 37, the first processing section 39, the second processing section 40, and the third processing section 41.

The drying processing section 37 performs drying processing on a lot. Specifically, each of the tank LPD1 and the tank LPD2 of the drying processing section 37 accommodates the lot and performs drying processing on the substrates W in the lot. The second transport mechanism WTR transports the lot into and out of each of the tank LPD1 and the tank LPD2.

The first processing section 39 is disposed adjacent to the drying processing section 37. The tank ONB1 of the first processing section 39 performs rinsing processing with a rinse liquid on the substrates W in a lot, for example. The tank CHB1 performs processing (e.g., etching processing) with a chemical liquid on the substrates W in the lot, for example.

The sub-transport mechanism LF1 of the transport mechanism CV performs lot delivery to and from the second transport mechanism WTR in addition to lot transport in the first processing section 39. Furthermore, the sub-transport mechanism LF1 immerses a lot in the tank ONB1 or the tank CHB1 and pulls the lot out of the tank ONB1 or the tank CHB1.

The second processing section 40 is disposed adjacent to the first processing section 39. The tank ONB2 of the second processing section 40 has the same configuration as the tank ONB1 and performs the same processing as the tank ONB1. The tank CHB2 has the same configuration as the tank CHB1 and performs the same processing as the tank CHB1. The sub-transport mechanism LF2 of the transport mechanism CV performs lot delivery to and from the second transport mechanism WTR in addition to lot transport in the second processing section 40. Furthermore, the sub-transport mechanism LF2 immerses a lot in the tank ONB2 or the tank CHB2 and pulls the lot out of the tank ONB2 or the tank CHB2.

The third processing section 41 is disposed adjacent to the second processing section 40. The tank ONB3 of the third processing section 41 has the same configuration as the tank ONB1 and performs the same processing as the tank ONB1. The tank CHB3 has the same configuration as the tank CHB1 and performs the same processing as the tank CHB1. The sub-transport mechanism LF3 of the transport mechanism CV performs lot delivery to and from the second transport mechanism WTR in addition to lot transport in the third processing section 41. Furthermore, the sub-transport mechanism LF3 immerses a lot in the tank ONB3 or the tank CHB3 and pulls the lot out of the tank ONB3 or the tank CHB3.

In the second embodiment, the tank LPD1 and the tank LPD2 are also referred to below as drying tank LPD1 and drying tank LPD2, respectively. The tank ONB1 is also referred to as first rinse tank ONB1, the tank ONB2 is also referred to as second rinse tank ONB2, and the tank ONB3 is also referred to as third rinse tank ONB3. The tank CHB1 is referred to as first chemical liquid tank CHB1, the tank CHB2 is referred to as second chemical liquid tank CHB2, and the tank CHB3 is referred to as third chemical liquid tank CHB3.

The first chemical liquid tank CHB1 stores a first chemical liquid therein. The first chemical liquid is BHF, for example. The second chemical liquid tank CHB2 stores a second chemical liquid therein. The second chemical liquid is TMAH, for example. Note that the second chemical liquid may include TMAH and IPA. The second chemical liquid tank CHB2 corresponds to an example of a “chemical liquid tank” in the present disclosure. The second chemical liquid corresponds to an example of a “chemical liquid” in the present disclosure. The second rinse tank ONB2 corresponds to an example of a “rinse tank” in the present disclosure.

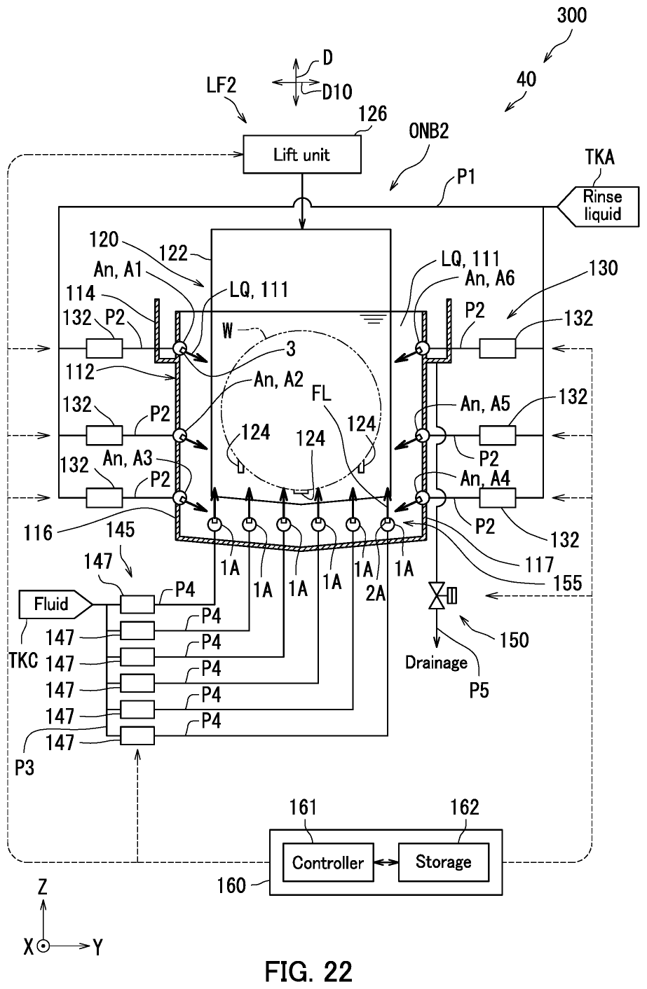

With reference to FIG. 22, the second rinse tank ONB2 is described next. FIG. 22 is a schematic cross-sectional view of the second rinse tank ONB2. As illustrated in FIG. 22, the configuration of the second processing section 40 of the substrate processing apparatus 300 is the same as that in the substrate processing apparatus 100 in FIG. 1. However, the second processing section 40 includes a fluid supply section 155 in place of the bubble supply section 135 in FIG. 1. Furthermore, the second processing section includes a fluid adjustment section 145 in place of the bubble adjustment section 140 in FIG. 1. Furthermore, the second processing section 40 includes a second rinse tank ONB2 in place of the processing tank 110 in FIG. 1. The configuration of the second rinse tank ONB2 is the same as the configuration of the processing tank 110 in FIG. 1.

In the second embodiment, a processing liquid LQ is a rinse liquid. In the following, the rinse liquid as the processing liquid LQ is also referred to as “rinse liquid 111”. The second rinse tank ONB2 stores the rinse liquid 111 therein. The second rinse tank ONB2 includes a first side wall 116 and a second side wall 117 that face each other.

Processing liquid supply sections An supply the rinse liquid 111 to the interior of the second rinse tank ONB2 (specifically, an inner tank 112). As such, a processing liquid flow rate adjustment section 130 in the second embodiment adjusts the flow rate of the rinse liquid 111 supplied to the processing liquid supply sections An for each of the processing liquid supply sections An. The processing liquid supply sections An are disposed at the second rinse tank ONB2. Besides, the operations of the processing liquid supply sections An and the processing liquid flow rate adjustment section 130 according to the second embodiment are respectively the same as the operations of the processing liquid supply sections An and the processing liquid flow rate adjustment section 130 according to the first embodiment.

The processing liquid supply sections An each correspond to an example of a “rinse liquid supply section” in the present disclosure. Also, the processing liquid flow rate adjustment section 130 can be considered as “rinse liquid flow rate adjustment section” in the second embodiment.

Specifically, the processing liquid supply sections An include at least one first processing liquid supply section An. In the second embodiment, the processing liquid supply sections An include two or more first processing liquid supply sections An (A1 to A3). The first processing liquid supply sections An (A1 to A3) are arranged at the side of the first side wall 116 and supply the rinse liquid 111 to the interior of the second rinse tank ONB2. The processing liquid supply sections An include at least one second processing liquid supply section An. In the second embodiment, the processing liquid supply sections An include two or more second processing liquid supply sections An (A4 to A6). The second processing liquid supply sections An (A4 to A6) are arranged at the side of the second side wall 117 and supply the rinse liquid 111 to the interior of the second rinse tank ONB2. The first processing liquid supply sections An (A1 to A3) each correspond to an example of a “first rinse liquid supply section” in the present disclosure. The second processing liquid supply sections An (A4 to A6) each correspond to an example of a “second rinse liquid supply section” in the present disclosure.

A substrate holding section 120 holds substrates W and immerses the substrates W in the rinse liquid 111 stored in the second rinse tank ONB2. Note that the sub-transport mechanism LF2 includes the substrate holding section 120 and a lift unit 126. Furthermore, each configuration of the sub-transport mechanisms LF1 and the sub-transport mechanism LF3 is the same as the configuration of the sub-transport mechanism LF2.

The fluid supply section 155 is disposed in the interior of the second chemical liquid tank CHB2. The fluid supply section 155 supplies a fluid FL supplied from the fluid adjustment section 145 into the rinse liquid 111 in the second chemical liquid tank CHB2. The fluid FL is a liquid or a gas. When the fluid FL is a liquid, the fluid FL is a rinse liquid, for example. When the fluid FL is a gas, the gas is an inert gas, for example. Examples of the inert gas include nitrogen and argon. Note that when the fluid FL is a gas, the fluid supply section 155 is the same as the bubble supply section 135 in FIG. 1.

The fluid supply section 155 includes at least one fluid supply pipe 1A. In the second embodiment, the fluid supply section 155 includes a plurality of fluid supply pipes 1A. In the example illustrated in FIG. 22, the fluid supply section 155 includes six fluid supply pipes 1A. Note that, the number of the fluid supply pipes 1A is not limited particularly. The material of the fluid supply pipes 1A is the same as the material of the bubble supply pipes 1 in FIG. 1.

The configuration of the fluid supply pipes 1A is the same as the configuration of the bubble supply pipes 1 in FIG. 1. Specifically, each of the fluid supply pipes 1A has a plurality of fluid holes 2A. In the example illustrated in FIG. 22, the fluid holes 2A are directed upward in the vertical direction D. The fluid supply pipes 1A supply the fluid FL into the rinse liquid 111 by ejecting the fluid FL supplied from the fluid adjustment section 145 through the fluid holes 2A.

The fluid supply pipes 1A are arranged substantially in parallel to each other at intervals in plan view. Besides, the arrangement of the fluid supply pipes 1A is the same as the arrangement of the bubble supply pipes 1 in FIGS. 1 and 2. The fluid holes 2A of each of the fluid supply pipes 1A are arranged substantially on a straight line with a space in a direction in which the fluid supply pipes 1A extend. Besides, the configuration and arrangement of the fluid holes 2A are the same as the configuration and arrangement of the bubble holes 2 in FIGS. 1 and 2.

In detail, each of the fluid supply pipes 1A supplies the fluid FL through the fluid holes 2A to the rinse liquid 111 from below the substrates W in a state in which the substrates W are immersed in the rinse liquid 111.

The fluid adjustment section 145 adjusts the amount of the fluid FL supplied to the rinse liquid 111 by adjusting the flow rate of the fluid FL supplied to the fluid supply pipes 1A for each of the fluid supply pipes 1A. Adjustment of the flow rate of the fluid FL includes keeping the flow rate of the fluid FL constant, increasing the flow rate of the fluid FL, decreasing the flow rate of the fluid FL, and setting the flow rate of the fluid FL to zero. In the second embodiment, the fluid adjustment section 145 switches between supply and supply stop of the fluid FL to the fluid supply pipes 1A for each of the fluid supply pipes 1A. Note that when the fluid FL is a gas, the fluid adjustment section 145 is the same as the bubble adjustment section 140 in FIG. 1.

The fluid adjustment section 145 includes a plurality of fluid adjustment mechanisms 147, each for corresponding to one of the fluid supply pipes 1A. The supply pipes P4 are each provided for a corresponding one of the fluid adjustment mechanisms 147. One end of each of the supply pipes P4 is connected to a corresponding one of the fluid supply pipes 1A. The other end of each of the supply pipes P4 is connected to a common pipe P3. The common pipe P3 is connected to a fluid supply source TKC.

The fluid adjustment mechanisms 147 are each disposed in a corresponding one of the supply pipes P4. The fluid adjustment mechanisms 147 supply the fluid FL supplied from the fluid supply source TKC and the common pipe P3 to the corresponding fluid supply pipes 1A through the corresponding supply pipes P4. Furthermore, the fluid adjustment mechanisms 147 adjust the flow rate of the fluid FL supplied to the corresponding fluid supply pipes 1A. As a result, the amount of the fluid FL supplied to the rinse liquid 111 is adjusted for each of the fluid supply pipes 1A. In the second embodiment, the fluid adjustment mechanisms 147 switch between supply and supply stop of the fluid FL to the corresponding fluid supply pipes 1A.

The fluid adjustment mechanisms 147 have the same configuration as the bubble adjustment mechanisms 142 in FIG. 2. For example, the fluid adjustment mechanisms 147 each include a flow rate adjustment valve, a flowmeter, a filter, and a valve. Note that the fluid adjustment mechanisms 147 each may include a mass flow controller in place of the flow rate adjustment valve and the flowmeter.

The control device 160 (controller 161) controls the elements of configuration in the second processing section 40 and the elements of configuration in the sub-transport mechanism LF2.

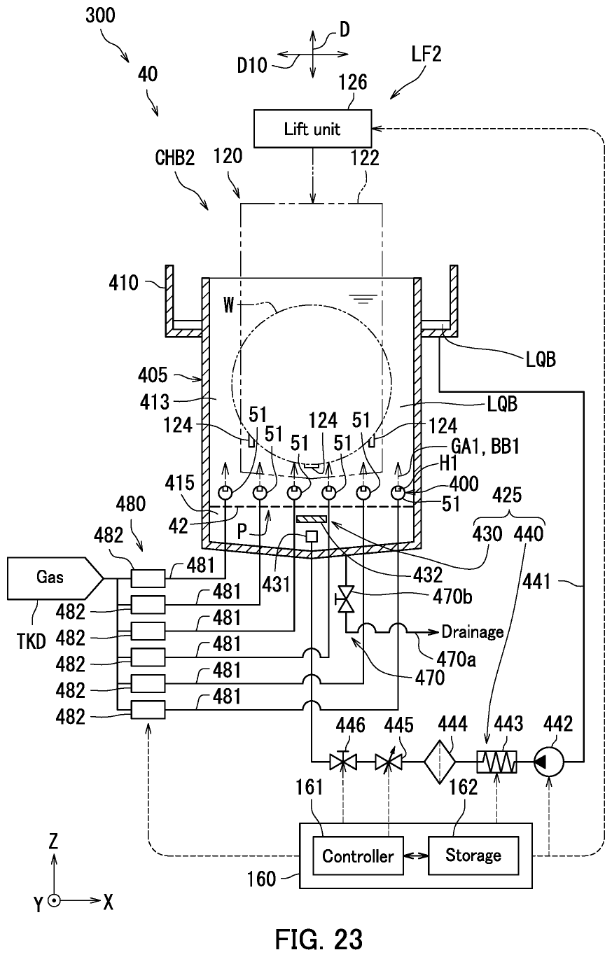

With reference to FIG. 23, the second chemical liquid tank CHB2 is described next. FIG. 23 is a schematic cross-sectional view of the second chemical liquid tank CHB2. As illustrated in FIG. 23, the second processing section 40 includes a second chemical liquid tank CHB2, a chemical liquid guide section 425, a drainage section 470, a bubble adjustment section 480, and a bubble supply section 400. The second chemical liquid tank CHB2 includes an inner tank 405 and an outer tank 410.

The second chemical liquid tank CHB2 stores a second chemical liquid LQB therein. Specifically, the inner tank 405 stores therein the second chemical liquid LQB into which a plurality of substrates W are to be immersed. The outer tank 410 is disposed outside the inner tank 405 to surround the inner tank 405. A portion of the second chemical liquid LQB stored in the inner tank 405 that has overflown from the inner tank 405 flows into the outer tank 410.

The sub-transport mechanism LF2 includes a substrate holding section 120 and a lift unit 126. The substrate holding section 120 immerses the substrates W aligned at intervals in the second chemical liquid LQB stored in the inner tank 450. As a result, the substrates W are processed with the second chemical liquid LQB.

The bubble supply section 400 supplies a gas GA1 to the second chemical liquid LQB stored in the inner tank 405. The gas GA1 is an inert gas, for example. Examples of the inert gas include nitrogen and argon. Specifically, the bubble supply section 400 supplies bubbles BB1 of the gas GA1 to the second chemical liquid LQB stored in the inner tank 405.

In detail, the bubble supply section 400 is disposed in the interior of the inner tank 405. The bubble supply section 400 includes at least one bubble supply pipe 51. In the second embodiment, the bubble supply section 400 includes a plurality of bubble supply pipes 51. The bubble supply pipes 51 are arranged on the side of the bottom of the inner tank 405. The bubble supply pipes 51 each include a plurality of bubble holes H1.

The bubble supply pipes 51 supply the bubbles BB1 to the second chemical liquid LQB through the bubble holes H1 by ejecting the gas GA1 from each of the bubble holes H1. The bubble supply pipes 51 are bubbler tubes, for example.

The bubble adjustment section 480 adjusts the flow rate of the gas GA1 supplied to the bubble supply section 400. Specifically, the bubble adjustment section 480 adjusts the flow rate of the gas GA1 supplied to the bubble supply section 400 to adjust the amount of the bubbles BB1 supplied by the bubble supply sections 400 to the second chemical liquid LQB.

Specifically, the bubble adjustment section 480 supplies the gas GA1 supplied from the gas supply source TKD to the bubble supply pipes 51 through the respective supply pipes 481. Further specifically, the bubble adjustment section 480 includes a plurality of bubble adjustment mechanisms 482. The bubble adjustment mechanisms 482 supply the gas GA1 to the corresponding bubble supply pipes 51 through the corresponding supply pipes 481. Furthermore, the bubble adjustment mechanisms 482 adjust the flow rate of the gas GA1 supplied to the corresponding bubble supply pipes 51.

Besides, the configuration and operation of the bubble adjustment section 480 are the same as the configuration and operation of the bubble adjustment section 140 in FIG. 1. The configuration and operation of the bubble adjustment mechanisms 482 are the same as the configuration and operation of the bubble adjustment mechanisms 142 in FIG. 1. Furthermore, the configuration and operation of the bubble supply section 400 are the same as the configuration and operation of the bubble supply section 135 in FIG. 1. The configuration and operation of the bubble supply pipes 51 are the same as the configuration and operation of the bubble supply pipes 1 in FIG. 1.

The chemical liquid guide section 425 guides the second chemical liquid LQB stored in the outer tank 410 to the inner tank 405. As a result, the second chemical liquid LQB is circulated between the inner tank 405 and the outer tank 410.

The chemical liquid guide section 425 includes a guide section 430 and a circulation section 440.

The guide section 430 guides the second chemical liquid LQB to the inner tank 405. The guide section 430 is disposed below the bubble supply sections 400 (specifically, the bubble supply pipes 51) in the interior of the inner tank 405.

Specifically, the guide section 430 includes a plate 42. The plate 42 divides the interior of the inner tank 405 to define a processing chamber 413 and a guide chamber 415. The processing chamber 413 is a chamber above the plate 42 in the interior of the inner tank 405. The guide chamber 415 is a chamber below the plate 42 in the interior of the inner tank 405.

The plate has a plurality of chemical liquid holes P. The chemical liquid holes P are arranged throughout the plate 42. The bubble supply pipes 51 are arranged above the plate and below the substrates W in the interior of the inner tank 405.

The guide section 430 guides the second chemical liquid LQB toward the inner tank 405 upward through the chemical liquid holes P in a state in which the second chemical liquid LQB is stored in the inner tank 405. Accordingly, the guide section 430 can generate a laminar flow of the second chemical liquid LQB supplied from the circulation section 440. The laminar flow of the second chemical liquid LQB flows upward substantially in the vertical direction D from the chemical liquid holes P.

Specifically, the guide section 430 includes at least one ejection section 431 and at least one dispersion plate 432. The ejection section 431 is a nozzle or a tube, for example. The dispersion plate 432 is substantially flat plate shaped, for example. The ejection section 431 and the dispersion plate 432 are arranged in the guide chamber 415.

The ejection section 431 ejects the second chemical liquid LQB supplied from the circulation section 440 toward the dispersion plate 432. Accordingly, the second chemical liquid LQB abuts on the dispersion plate 432 with a result that the pressure of the second chemical liquid LQB is dispersed by the dispersion plate 432. The second chemical liquid LQB of which pressure has been dispersed by the dispersion plate 432 spreads substantially in the horizontal direction in the guide chamber 415. Furthermore, the second chemical liquid LQB is supplied to the processing chamber 413 as a laminar flow flowing upward from each chemical liquid hole P of the plate 42.

The circulation section 440 circulates the second chemical liquid LQB in the inner tank 405 by supplying to the guide section 430 the second chemical liquid LQB overflowing from the inner tank 405 and flowing into the outer tank 410.

Specifically, the circulation section 440 includes a circulation tube 441, a pump 442, a heater 443, a filter 444, an adjustment valve 445 and a valve 446.

The circulation tube 441 connects the outer tank 410 and the inner tank 405. The circulation tube 441 guides to the inner tank 405 again the second chemical liquid LQB overflowing from the inner tank 405 and flowing into the outer tank 410. The circulation tube 441 has a downstream end connected to the guide section 430 (specifically, the ejection section 431).

The pump 442 sends out the second chemical liquid LQB toward the inner tank 405 from the outer tank 410 through the circulation tube 441. The ejection section 431 ejects the second chemical liquid LQB supplied from the circulation tube 441. The filter 444 filtrates the second chemical liquid LQB flowing in the circulation tube 441.

The heater 443 heats the second chemical liquid LQB flowing in the circulation tube 441. The opening of the adjustment valve 445 is controlled to adjust the flow rate of the second chemical liquid LQB supplied to the ejection section 431. The valve 446 opens and closes the circulation tube 441. The drainage section 470 discharges the second chemical liquid LQB in the inner tank 405. The drainage section 470 includes a drainage pipe 470a and a valve 470b. The control device 160 (controller 161) controls each configuration of the second processing section 40 and each elements of configuration in the sub-transport mechanism LF2.

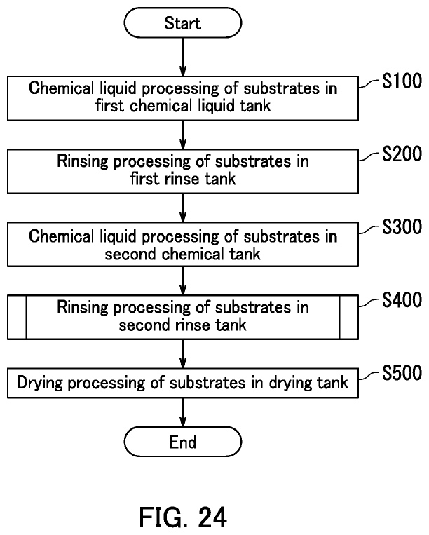

With reference to FIGS. 21 to 25, a substrate processing method implemented by the substrate processing apparatus 300 is described next. FIG. 24 is a flowchart depicting the substrate processing method according to the second embodiment. As depicted in FIG. 24, the substrate processing method includes Steps S100 to S500. Steps S100 to S500 are executed under control of the controller 161.

As depicted in FIGS. 21 and 24, the sub-transport mechanism LF1 (substrate holding section) first immerses a plurality of substrates W in the first chemical liquid stored in the first chemical liquid tank CHB1 in Step S100. As a result, the substrates W are processed with the first chemical liquid. That is, the first processing section 39 processes the substrates W with the first chemical liquid stored in the first chemical liquid tank CHB1. Once processing in the first chemical liquid tank CHB1 is completed, the sub-transport mechanism LF1 (substrate holding section) pulls the substrates W out of the first chemical liquid in the first chemical liquid tank CHB1.

Next in Step S200, the sub-transport mechanism LF1 (substrate holding section) immerses the substrates W in the rinse liquid stored in the first rinse tank ONB1. As a result, the substrates W are rinsed with the rinse liquid. That is, the first processing section 39 rinses the substrate W with the rinse liquid stored in the first rinse tank ONB1. Once rinsing processing in the first rinse tank ONB1 is completed, the sub-transport mechanism LF1 (substrate holding section) pulls the substrates W out of the rinse liquid in the first rinse tank ONB1. The second transport mechanism WTR transports the substrates W from the first processing section 39 to the second processing section 40 and delivers the substrates W to the sub-transport mechanism LF2.

Next in Step S300, the sub-transport mechanism LF2 (substrate holding section 120) immerses the substrates W in the second chemical liquid LQB stored in the second chemical liquid tank CHB2. As a result, the substrates W are processed with the second chemical liquid LQB. That is, the second processing section 40 processes the substrates W with the second chemical liquid LQB stored in the second chemical liquid tank CHB2. Once processing in the second chemical liquid tank CHB2 is completed, the sub-transport mechanism LF2 (substrate holding section 120) pulls the substrates W out of the second chemical liquid LQB in the second chemical liquid tank CHB2.

Next in Step S400, the sub-transport mechanism LF2 (substrate holding section 120) immerses the substrates W in the rinse liquid 111 stored in the second rinse tank ONB2. As a result, the substrates W are rinsed with the rinse liquid 111. That is, the second processing section 40 rinses the substrates W with the rinse liquid 111 stored in the second rinse tank ONB2. Once rinsing processing in the second rinse tank ONB2 is completed, the sub-transport mechanism LF2 (substrate holding section 120) pulls the substrates W out of the rinse liquid 111 in the second rinse tank ONB2. The second transport mechanism WTR transports the substrates W from the second processing section 40 to the drying tank LPD2.

Next in Step S500, the drying tank LPD2 dries the substrates W. Once drying by the drying tank LPD2 is completed, the second transport mechanism WTR takes the substrates W out of the drying tank LPD2. The substrate processing method ends then.

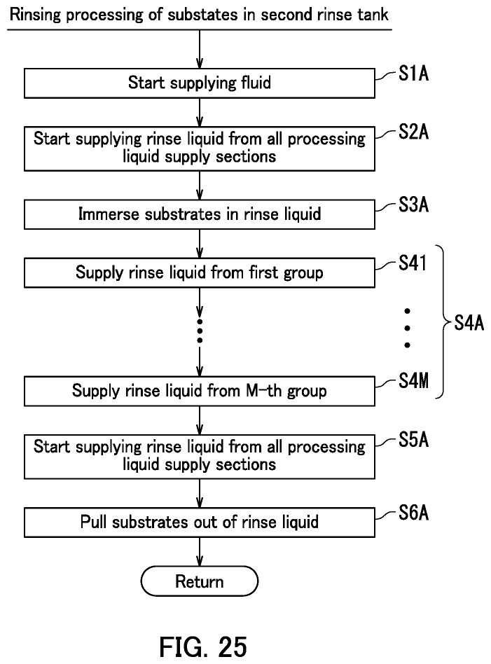

FIG. 25 is a flowchart depicting the details of Step S400 in FIG. 24. That is, FIG. 25 depicts the rinsing processing of the substrates W in the second rinse tank ONB2. As depicted in FIG. 25, the rinsing processing (Step S400 in FIG. 24) of the substrates W in the second rinse tank ONB2 includes Steps S1A to S6A. Steps S1A to S6A are executed under control of the controller 161. In the description of the substrate processing method, a first group G1 to an M-th group GM are set in the second rinse tank ONB2. “M” represents an integer of at least 2.

As depicted in FIGS. 22 and 25, each fluid supply pipe 1A of the fluid supply section 155 starts supply of the fluid FL to the rinse liquid 111 stored in the second rinse tank ONB2 from below the substrates in Step S1A. Step S1A corresponds to an example of “supplying a fluid” in the present disclosure.

Next in Step S2A, supply of the rinse liquid 111 from all of the processing liquid supply sections An toward the rinse liquid 111 stored in the second rinse tank ONB2 starts.

Next in Step S3A, the substrate holding section 120 immerses, in the rinse liquid 111 stored in the second rinse tank ONB2, the substrates W having been processed with the second chemical liquid LQB stored in the second chemical liquid tank CHB2 different from the second rinse tank ONB2. Step S3A corresponds to an example of “immersing” in the present disclosure.

Next in Step S4A, the rinse liquid 111 is supplied to the interior of the second rinse tank ONB2 from at least one processing liquid supply sections An while the processing liquid supply sections An are switched. Step S4A corresponds to an example of “supplying the rinse liquid” in the present disclosure.

Specifically, Step S4A includes Steps S41, S42, S43, S44, . . . , and S4M. First in Step S41, the rinse liquid 111 is supplied toward the interior of the second rinse tank ONB2 from a processing liquid supply section An belonging to the first group G1. Next in Step S42, the rinse liquid 111 is supplied toward the interior of the second rinse tank ONB2 from a processing liquid supply section An belonging to the second group G2. Thereafter, Steps S43, S44, . . . , and S4M are executed in a sequential manner. In Step S4M, the rinse liquid 111 is supplied toward the interior of the second rinse tank ONB2 from a processing liquid supply section An belonging to the M-th group GM. In the manner described above, the processing liquid supply sections An belonging to the respective groups supply the rinse liquid 111 for different periods that are mutually different for each of the groups in Step S4A.

Next in Step S5A, supply of the rinse liquid 111 from all of the processing liquid supply sections An toward the rinse liquid 111 stored in the second rinse tank ONB2 starts.

Next in Step S6A, the substrate holding section 120 pulls the substrates W out of the rinse liquid 111. The substrate processing method ends then.

As has been described with reference to FIG. 25, according to the second embodiment, at least one processing liquid supply section An supplies the rinse liquid 111 to the interior of the second rinse tank ONB2 (step S4A). Furthermore, the fluid supply section 155 supplies the fluid FL to the rinse liquid 111 from below the substrates W (Step S1A). Specifically, the fluid supply pipes 1A each supply the fluid FL to the rinse liquid 111 in the second rinse tank ONB2. Furthermore, the fluid FL is supplied to the rinse liquid 111 in the second rinse tank ONB2 through the fluid holes 2A in each of the fluid supply pipes 1A. In the manner described above, the fluid FL is supplied toward the rinse liquid 111 from different locations on the side of the bottom of the second rinse tank ONB2.

The fluid FL facilitates replacement of the second chemical liquid LQB remaining on the substrates W with the rinse liquid 111. As such, according to the second embodiment, the second chemical liquid LQB is quickly replaced with the rinse liquid 111 even in the inner region AR2 in which the second chemical liquid LQB is more likely to remain than in the outer region AR1 (FIG. 20) of each substrate W. As a result, the processing amount (e.g., the etching amount) can become substantially even over the entire in-plane of each substrate W compared with a case in which the fluid FL is not supplied (e.g., the second reference example illustrated in FIG. 19). Thus, occurrence of unevenness in processing amount (e.g., etching amount) in the in-plane of each substrate W can be inhibited. In particular, as compared with a case in which the fluid FL is not supplied, the speed of replacement of the second chemical liquid LQB with the rinse liquid 111 can be increased in the entire in-plane of each substrate W in presence of the fluid FL supplied from different locations on the side of the bottom of the second rinse tank ONB2. That is, throughput of the rinsing processing can be increased.

One of the reasons why the fluid FL facilitates replacement of the second chemical liquid LQB with the rinse liquid 111 on each substrate W (surfaces of the substrates W) may be for example that the updraft of the fluid FL generates a turbulent flow on the surfaces of the substrates W to make the second chemical liquid LQB on the surfaces of the substrates W easily replaced with the rinse liquid 111. In other words, the updraft of the fluid FL generates a turbulent flow on the surfaces of the substrates W to inhibit the second chemical liquid LQB and the rinse liquid 111 from stagnating on the surfaces of the substrates W.

In particular, when the fluid FL is a rinse liquid, the replacement with the rinse liquid is more effectively done. That is, it is thought that the updraft of the fluid FL being the rinse liquid generates a turbulent flow of the rinse liquid on the surfaces of the substrates W to make the second chemical liquid LQB on the surfaces of the substrates W more easily replaced with the rinse liquid. In other words, the updraft of the fluid FL being the rinse liquid generates a turbulent flow on the surfaces of the substrates W to further inhibit the second chemical liquid LQB and the rinse liquid from stagnating on the surfaces of the substrates W. Furthermore, fresh rinse liquid can be effectively sent to the surfaces of the substrates W in presence of the updraft of the fluid FL being the rinse liquid.

Note that replacement of the second chemical liquid LQB with the rinse liquid 111 can be facilitated more effectively when the fluid FL is a gas than when the fluid FL is a liquid. This is because the updraft velocity of the fluid FL is higher and a turbulent flow can be more effectively generated when the fluid FL is a gas than when the fluid FL is a liquid.

Furthermore, in the second embodiment, the following is thought as a reason why occurrence of unevenness in processing amount (e.g., the etching amount) can be inhibited in the in-plane of each substrate W. That is, non-uniform flow in the processing tank 110 due to the rinse liquid 111 being supplied from the processing liquid supply sections An is rectified by the updraft of the fluid FL supplied from the different locations on the side of the bottom of the second rinse tank ONB2. As a result, it is through that efficiency of replacement is equalized between in the outer region AR1 (FIG. 20) and in the inner region AR2 (FIG. 20) of each substrate W. Thus, occurrence of unevenness in processing amount in the in-plane of each substrate W can be inhibited.

Note that when the fluid FL is not supplied, for example, the rinse liquid 111 may flow into the outer region AR1 (FIG. 20) more easily than into the inner region AR2 (FIG. 20) of each substrate W in presence of the flow in the processing tank 110 resulting from supply of the rinse liquid 111 from the processing liquid supply sections An. Therefore, when the fluid FL is not supplied, the second chemical liquid LQB and the rinse liquid 111 may tend to stagnate on the inner region AR2 of each substrate W. In view of the foregoing, in the second embodiment, the fluid FL is supplied from different locations on the side of the bottom of the second rinse tank ONB2 to rectify by the updraft of the fluid FL non-uniform flow in the processing tank 110 resulting from the rinse liquid 111 being supplied from the processing liquid supply sections An. As a result, efficiency of replacement of the second chemical liquid LQB with the rinse liquid 111 is thought to be equalized between in the outer region AR1 and in the inner region AR2 of each substrate W.

Furthermore, according to the second embodiment, the rinsing processing with a rinse liquid (also referred to below as “rinse liquid RN”) is performed in the first rinse tank ONB1, the chemical liquid processing with the second chemical liquid LQB is performed in the second chemical liquid tank CHB2, and the rinsing processing with the rinse liquid 111 is performed in the second rinse tank ONB2. That is, the rinsing processing and the chemical liquid processing are performed in different tanks. Therefore, replacement of the rinse liquid RN, the rinse liquid 111, and the second chemical liquid LQB is not necessary for each lot. As a result, each amount of use of the rinse liquid RN, the rinse liquid 111, and the second chemical liquid LQB can be reduced compared with those in the first reference example (FIG. 18). That is, the rinse liquid RN, the rinse liquid 111, and the second chemical liquid LQB can be reused. Accordingly, each waste amount of the rinse liquid RN, the rinse liquid 111, and the second chemical liquid LQB can be reduced.

### (Variation)

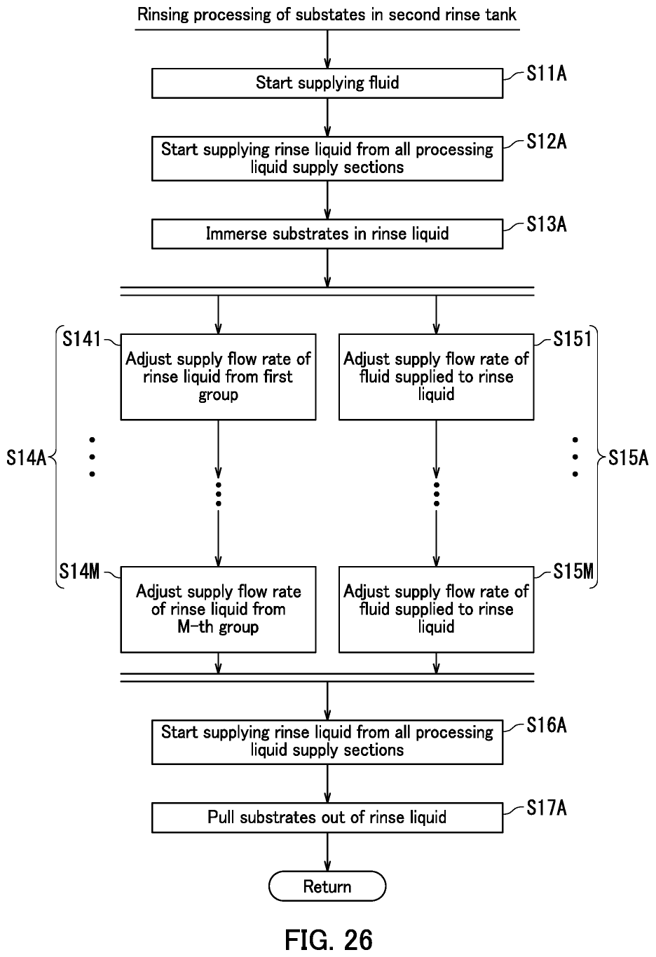

With reference to FIGS. 22 and 26, a variation of the second embodiment is described. The variation mainly differs from the second embodiment, which executes supply start and supply stop of the rinse liquid 111 and supply start and supply stop of the fluid FL, in that the supply flow rate of the rinse liquid 111 and the supply flow rate of the fluid FL are precisely adjusted. The following mainly describes difference of the variation from the second embodiment.

In the variation, a processing liquid flow rate adjustment section 130 illustrated in FIG. 22 adjusts the supply flow rate of the rinse liquid 111 for each of processing liquid supply sections An.

In the variation, adjustment of the supply flow rate of the rinse liquid 111 includes change of the supply flow rate of the rinse liquid 111 from a processing liquid supply section in one group or change of the supply flow rate of the rinse liquid 111 from processing liquid supply sections An in a plurality of groups in addition to supply start and supply stop of the rinse liquid 111. Change of the supply flow rate of the rinse liquid 111 includes stepwise change of the supply low rate or continuous change of the supply flow rate.

Furthermore, a fluid adjustment section 145 in the variation adjusts the supply flow rate of the fluid FL for each of the fluid supply pipes 1A.

In the variation, adjustment of the supply flow rate of the fluid FL includes change of the supply flow rate of the fluid FL in addition to the supply start and supply stop of the fluid FL. Change of the supply flow rate of the fluid FL includes stepwise change of the flow rate or continuous change of the flow rate.

With reference to FIGS. 24 and 26, a substrate processing method according to the variation is described next. The substrate processing method is implemented by the substrate processing apparatus 300. As depicted in FIG. 24, the substrate processing method includes Steps S100 to S500. FIG. 26 is a flowchart depicting Step S400 in FIG. 24 according to the variation of the second embodiment. That is, FIG. 26 depict rinsing processing of the substrates W in the second rinse tank ONB2 according to the variation. As depicted in FIG. 26, the rinsing processing (Step S400 in FIG. 24) of the substrates W in the second rinse tank ONB2 includes Steps S11A to S17A. Steps S11A to S17A are executed under control of the controller 161.

Steps S11A to S13A in FIG. 26 are the same as S1A to S3A in FIG. 25, respectively.

As depicted in FIG. 26, Step S13A is followed by parallel execution of Steps S14A and S15A.

In Step S14A, the supply flow rate of the rinse liquid 111 is adjusted for each of the processing liquid supply sections An in the first group G1 to the M-th group GM by the processing liquid flow rate adjustment section 130.

Specifically, Step S14A includes Steps S141, S142, S143, S144, . . . , and S14M. First in Step S141, the processing liquid flow rate adjustment section 130 adjusts the supply flow rate of the rinse liquid 111 supplied from a processing liquid supply section An belonging to the first group G1. Next in Step S142, the processing liquid flow rate adjustment section 130 adjusts the supply flow rate of the rinse liquid 111 supplied from a processing liquid supply section An belonging to the second group G2. Thereafter, Steps S143, S144, . . . , and S14M are executed in a sequential manner. In Step S14M, the processing liquid flow rate adjustment section 130 adjusts the supply flow rate of the rinse liquid 111 supplied from a processing liquid supply section An belonging to the M-th group GM. In the manner described above, the supply flow rate of each of the processing liquid supply sections An belonging to the respective groups is adjusted for each of the groups for different periods that are mutually different for each of the groups.

In Step S15A by contrast, the fluid adjustment section 145 adjusts the supply flow rate of the fluid FL for each of the fluid supply pipes 1A in response to supply of the rinse liquid 111 by the first group F1 to the M-th group GM.

Specifically, Step S15A includes Steps S151, S152, S153, S154, . . . , and S15M. First in Step S151, the fluid adjustment section 145 adjusts the supply flow rate of the fluid FL in response to supply of the rinse liquid 111 from the processing liquid supply section An belonging to the first group G1. Next in Step S152, the fluid adjustment section 145 adjusts the supply flow rate of the fluid FL in response to supply of the rinse liquid 111 from the processing liquid supply section An belonging to the second group G2. Thereafter, Steps S153, S154, . . . , and S15M are executed in a sequential manner. In Step S15M, the fluid adjustment section 145 adjusts the supply flow rate of the fluid FL in response to supply of the rinse liquid 111 from the processing liquid supply section An belonging to the M-th group GM. In the manner described above, the supply flow rate of the fluid FL is adjusted in response to supply of the rinse liquid 111 by each group in Step S15A.

Next in Step S16A, supply of the rinse liquid 111 from all of the processing liquid supply sections An toward the rinse liquid 111 stored in the second rinse tank ONB2 starts.

Next in Step S17A, the substrate holding section 120 pulls the substrates W out of the rinse liquid 111. The substrate processing method ends then.

Embodiments (including variations) of the present disclosure have been described so far with reference to the drawings. However, the present disclosure is not limited to the above embodiments and may be implemented in various manners within a scope not departing from the gist thereof. Various elements of configuration disclosed in the above embodiments can be varied as appropriate. For example, some of the elements of configuration indicated in an embodiment may be added to another embodiment. Alternatively or additionally, some of all the elements of configuration indicated in an embodiment may be omitted from the embodiment.

The drawings schematically illustrate elements of configuration in order to facilitate understanding. Properties such as the thickness, length, number, and intervals of each element of configuration illustrated in the drawings may differ from actual properties in order to facilitate preparation of the drawings. Furthermore, each element of configuration indicated in the above embodiments is an example and not a particular limitation. Various alterations may be made so long as there is no substantial deviation from the effects of the present disclosure.
(1) The direction of the processing liquid holes 3 of the processing liquid supply sections An in FIG. 1 is not particularly limited. For example, the processing liquid holes 3 may be directed in the horizontal direction or directed diagonally upward. Furthermore, the direction of the bubble holes 2 in the bubble supply pipes 1 is not particularly limited. For example, the bubble holes 2 may be directed diagonally upward.
(2) The number of the first processing liquid supply sections An in FIG. 1 is not particularly limited and may be one, two, or four or more. Likewise, the number of the second processing liquid supply sections An is not particularly limited and may be one, two, or four or more. Furthermore, the number of the bubble supply pipes 1 is also not limited particularly.
(3) Each of the processing liquid flow rate adjustment mechanisms 132 in FIG. 2 may not include the flowmeter a1 and the adjustment valve a2. Furthermore, each of the bubble adjustment mechanisms 142 may not include the adjustment valve b1, the flowmeter b2, and the filter b3.
(4) The mechanism for supplying the bubbles BB in FIG. 1 is not limited to the bubble supply pipes 1. For example, the bubbles BB may be supplied through a plurality of holes formed in a punched plate provided in the lower part of the processing tank 110.
(5) The processing liquid supply sections An constituting the respective groups in FIG. 1 can be determined arbitrarily and are not limited particularly. Furthermore, the number of the processing liquid supply sections An constituting each of the groups can be any number and is not limited particularly. The number of the groups for the processing liquid supply sections An is not limited particularly as long as it is at least 2. The number of the processing liquid supply sections An may be the same as or different from one another among the groups. Furthermore, processing liquid supply sections An constituting the respective groups may be arranged symmetrically or asymmetrically with respect to the center line extending in the vertical direction D.
(6) The flow rate of the gas GA may not be adjusted in Step S15 in the substrate processing method in the second variation described with reference to FIG. 11. Furthermore, the supply flow rate of the processing liquid LQ may not be adjusted in Step S14 in the substrate processing method. In other words, Step S4 in FIG. 10 may be executed in place of Step S14.
(7) It is possible that reduction in flow rate of the processing liquid LQ in a certain group is followed by switching to the next group.
(8) In the fourth variation, the shape of the areas 15 and 16 is not particularly limited and may be triangular or rectangular, for example.
(9) In the fourth variation, the machine learning may be executed using one lot of (e.g., 25 or 50) training substrates Wa. In this case, unevenness in processing with the processing liquid LQ can be reduced among the substrates W in the lot. Furthermore, machine learning may be executed for example using a training substrate Wa at the center in the second direction D20, a training substrate Wa at one end in the second direction D20, and a training substrate Wa at the other end in the second direction D20 among the training substrates Wa in one lot. In also this case, unevenness in processing with the processing liquid LQ can be reduced among the substrates W in the lot.

What is claimed is:

1. A substrate processing apparatus comprising:
a processing tank that stores a processing liquid therein;
a substrate holding section that holds a substrate and immerses the substrate in the processing liquid stored in the processing tank;
a bubble supply section that is disposed in the processing tank and that supplies bubbles to the processing liquid from below the substrate; and
a plurality of processing liquid supply sections that are disposed at the processing tank and that supply the processing liquid to an interior of the processing tank, wherein
the processing tank includes a first side wall and a second side wall that face each other, and
the processing liquid supply sections include:
one or more first processing liquid supply sections that are disposed on a side of the first side wall and that supply the processing liquid toward the bubbles; and
one or more second processing liquid supply sections that are disposed on a side of the second side wall and that supply the processing liquid toward the bubbles.

2. The substrate processing apparatus according to claim 1, wherein
two or more processing liquid supply sections of the processing liquid supply sections each belong to at least one of groups that are mutually different, and
to each of the groups, at least one processing liquid supply section of the processing liquid supply sections belongs, and
the processing liquid supply sections belonging to the respective groups supply the processing liquid toward the bubbles for periods that are mutually different for each of the groups.

3. The substrate processing apparatus according to claim 2, wherein
the one or more first processing liquid supply sections are provided as a plurality of first liquid supply sections,
the one or more second processing liquid supply sections are provided as a plurality of second liquid supply sections,
the groups includes a first group, a second group, and a third group,
the first group includes at least one first processing liquid supply section of the first processing liquid supply sections and does not include the second processing liquid supply sections,
the second group includes at least one second processing liquid supply section of the second processing liquid supply sections and does not include the first processing liquid supply sections, and
the third group includes at least one first processing liquid supply section of the first processing liquid supply sections and at least one second processing liquid supply section of the second processing liquid supply sections.

4. The substrate processing apparatus according to claim 2, further comprising:
storage that stores therein a trained model constituted through learning training data; and
a controller that controls the storage, wherein
the training data includes processing amount information and processing condition information,
the processing amount information includes information indicating a processing amount of a training substrate processed with a training processing liquid,
the processing condition information includes at least: information indicating at least one training processing liquid supply section in each of training groups; and information indicating timing of when each of the training groups supplies the training processing liquid,
the controller inputs input information to the trained model to acquire output information from the trained model,
the input information includes information indicating a target value of a processing amount of the substrate to be processed with the processing liquid,
the output information includes at least: information indicating one or more processing liquid supply sections in each of the groups; and information indicating timing of when each of the groups is to supply the processing liquid, and
the controller controls the processing liquid supply sections based on the output information.

5. The substrate processing apparatus according to claim 1, further comprising
a processing liquid flow rate adjustment section that adjusts a supply flow rate of the processing liquid for each of the processing liquid supply sections.

6. The substrate processing apparatus according to claim 1, wherein
the bubble supply section includes a plurality of bubble supply pipes that each receive supply of a gas to supply the bubbles to the processing liquid, and
the substrate processing apparatus further comprises a bubble adjustment section that adjusts a supply flow rate of the gas for each of the bubble supply pipes.

7. The substrate processing apparatus according to claim 1, wherein
the processing liquid is a rinse liquid, and
the substrate holding section immerses, in the rinse liquid stored in the processing tank, the substrate having been processed with a chemical liquid stored in a chemical liquid tank different from the processing tank.

8. A substrate processing apparatus comprising:
a rinse tank that stores a rinse liquid therein;
a substrate holding section that holds a substrate having been processed with a chemical liquid stored in a chemical liquid tank different from the rinse tank and that immerses the substrate in the rinse liquid stored in the rinse tank;
a fluid supply section that is disposed in the rinse tank and that supplies a fluid to the rinse liquid from below the substrate; and
a plurality of rinse liquid supply sections that are disposed at the rinse tank and that supply the rinse liquid to an interior of the rinse tank, wherein
the rinse tank includes a first side wall and a second side wall that face each other, and
the processing liquid supply sections include:
one or more first rinse liquid supply sections that are disposed on a side of the first side wall and that supply the rinse liquid to the interior of the rinse tank; and
one or more second rinse liquid supply sections that are disposed on a side of the second side wall and that supply the rinse liquid to the interior of the rinse tank.

9. A substrate processing method implemented by a substrate processing apparatus including a processing tank and a plurality of processing liquid supply sections, the method comprising:
immersing a substrate into a processing liquid stored in the processing tank;
supplying bubbles to the processing liquid from below the substrate; and
controlling behavior of the bubbles by supplying the processing liquid toward the bubbles from at least one processing liquid supply section of the processing liquid supply sections, wherein
the processing tank includes a first side wall and a second side wall that face each other, and
the processing liquid supply sections include:
one or more first processing liquid supply sections that are disposed on a side of the first side wall and that supply the processing liquid toward the bubbles; and
one or more second processing liquid supply sections that are disposed on a side of the second side wall and that supply the processing liquid toward the bubbles.

10. The substrate processing apparatus according to claim 9, wherein
two or more processing liquid supply sections of the processing liquid supply sections each belong to at least one of groups that are mutually different,
to each of the groups, at least one processing liquid supply section of the processing liquid supply sections belongs, and
in the controlling behavior of the bubbles, the processing liquid supply sections belonging to the respective groups supply the processing liquid toward the bubbles for periods that are mutually different for each of the groups.

11. The substrate processing method according to claim 10, wherein
the one or more first processing liquid supply sections are provided as a plurality of first liquid supply sections,
the one or more second processing liquid supply sections are provided as a plurality of second liquid supply sections,
the groups include a first group, a second group, and a third groups,
the first group includes at least one first processing liquid supply section of the first processing liquid supply sections and does not include the second processing liquid supply sections,
the second group includes at least one second processing liquid supply section of the second processing liquid supply sections and does not include the first processing liquid supply sections, and
the third group includes at least one first processing liquid supply section of the first processing liquid supply sections and at least one second processing liquid supply section of the second processing liquid supply sections.

12. The substrate processing method according to claim 10, further comprising
using a trained model in a manner to input information to a trained model to acquire output information from the trained model, the trained model being constituted through learning training data, wherein
the training data includes processing amount information and processing condition information,
the processing amount information includes information indicating a processing amount of a training substrate processed with a training processing liquid,
the processing condition information includes at least: information indicating at least one training processing liquid supply section in each of the training groups; and information indicating timing of when each of the training groups supplies the training processing liquid,
the input information includes information indicating a target value of a processing amount of the substrate to be processed with the processing liquid,
the output information includes at least: information indicating one or more processing liquid supply section in each of the groups; and information indicating timing of when each of the groups is to supply the processing liquid, and
in the controlling behavior of the bubbles, the processing liquid supply sections are controlled based on the output information.

13. The substrate processing method according to claim 9, wherein
in the controlling behavior of the bubbles, a supply flow rate of the processing liquid is adjusted for each of the processing liquid supply sections.

14. The substrate processing method according to claim 9, wherein
the substrate processing apparatus further includes a plurality of bubble supply pipes that each receive supply of a gas to supply the bubbles to the processing liquid, and
in the supplying bubbles, a supply flow rate of the gas is adjusted for each of the bubble supply pipes.

15. The substrate processing method according to claim 9, wherein
the processing liquid is a rinse liquid, and
in the immersing, the substrate having been processed with a chemical liquid stored in a chemical liquid tank different from the processing tank is immersed in the rinse liquid stored in the processing tank.

16. A substrate processing method implemented by a substrate processing apparatus including a rinse tank and a plurality of rinse liquid supply sections, the method comprising:
immersing a substrate having been processed with a chemical liquid stored in a chemical liquid tank different from the rinse tank in a rinse liquid stored in the rinse tank;
supplying a fluid to the rinse liquid from below the substrate; and
supplying the rinse liquid to an interior of the rinse tank from at least one of the rinse liquid supply sections, wherein
the rinse tank includes a first side wall and a second side wall that face each other, and
the rinse liquid supply sections include:
one or more first rinse liquid supply sections that are disposed on a side of the first side wall and that supply the rinse liquid to the interior of the rinse tank; and
one or more second rinse liquid supply sections that are disposed on a side of the second side wall and that supply the rinse liquid to the interior of the rinse tank.
